(19) United States
(12) Patent Application Publication
(10) Pub. No.: US 2021/0288192 A1
(43) Pub. Date: Sep. 16, 2021

(54) SENSOR ELEMENT AND ELECTRONIC DEVICE

(71) Applicant: SONY SEMICONDUCTOR SOLUTIONS CORPORATION, Kanagawa (JP)

(72) Inventors: Sozo YOKOGAWA, Kanagawa (JP); Itaru OSHIYAMA, Kanagawa (JP); Mikinori ITO, Kanagawa (JP)

(73) Assignee: SONY SEMICONDUCTOR SOLUTIONS CORPORATION, Kanagawa (JP)

(21) Appl. No.: 17/257,723

(22) PCT Filed: Jun. 28, 2019
(86) PCT No.: PCT/JP2019/025805

§ 371 Date: Jan. 4, 2021

(30) Foreign Application Priority Data
Jul. 13, 2018 (JP) 2018-133543

(51) Int. Cl. H01L 31/0236; H01L 27/146; H01L 31/0216

(52) U.S. Cl. CPC H01L 31/02363; H01L 31/02162; H01L 27/14612

(57) ABSTRACT

The present disclosure relates to a sensor element and an electronic device that enable sensor sensitivity to be improved. An optical-to-electrical conversion element that receives light in a predetermined wavelength range and performs optical-to-electrical conversion is formed in a semiconductor layer. A reflection suppressing part that suppresses reflection of the light is provided on a light receiving surface serving as a side on which the light enters the semiconductor layer. A transmission suppressing part that suppresses transmission through the semiconductor layer of the light that has been made incident from the light receiving surface is provided on a circuit surface serving as a side that is opposite to the light receiving surface of the semiconductor layer. The present technology can be applied, for example, to a reverse-surface irradiation type CMOS image sensor.

### TECHNICAL FIELD

The present disclosure relates to a sensor element and an electronic device, and in particular, a sensor element and an electronic device that enable sensor sensitivity to be improved.

### BACKGROUND ART

Conventionally, in a solid-state imaging element such as a charge coupled device (CCD) or complementary metal oxide semiconductor (CMOS) image sensor, crystalline silicon is used as a light absorbing layer, an optical-to-electrical converter, or the like. Furthermore, silicon includes a semiconductor for which a physical property value, specifically, an imaginary part of a complex refractive index (what is called an optical absorption coefficient), is small and that has a band gap at an energy level of 1.1 eV. Therefore, in order to enhance sensitivity, quantum efficiency, or the like with respect to near infrared rays, a silicon substrate itself needs to be thickened.

On the other hand, for the purpose of a solar battery that uses crystalline silicon similarly to the solid-state imaging element, in order to minimize a power generation efficiency, a cost, or the like of the solar battery, it is requested that a maximum amount of light be absorbed by using limited materials, and power generation efficiency be improved. Therefore, for the purpose of the solar battery, a light trapping structure is normally provided.

Meanwhile, a reverse-surface irradiation type solid-state imaging element has a structure in which a silicon substrate is thin. Therefore, a dominant component of incident light that has entered a light receiving surface propagates inside the silicon substrate serving as a light absorbing layer, and is transmitted through a circuit surface on an opposite side of the light receiving surface. Thus, unless a configuration in which the silicon substrate has a sufficient thickness (for example, 100 μm or the like) is employed, in the silicon substrate, optical-to-electrical conversion fails to be sufficiently performed on a long-wavelength component in visible and infrared wavelength ranges, and this is a principal factor of a deterioration in sensitivity, quantum efficiency, or the like.

Accordingly, as disclosed in Patent Document 1, for example, a solid-state imaging apparatus has been developed that is provided with an uneven structure on an interface on a light receiving surface side of an optical-to-electrical conversion region of each of the two-dimensionally arranged pixels and diffracts light by using the uneven structure.

### CITATION LIST

### Patent Document

Patent Document 1: Japanese Patent Application Laid-Open No. 2015-29054

### SUMMARY OF THE INVENTION

### Problems to be Solved by the Invention

Meanwhile, the solid-state imaging apparatus disclosed in Patent Document 1 described above has a structure in which 1st-order diffracted light of a diffracted component of incident light that has entered a silicon substrate from a light receiving surface can be trapped in a silicon substrate, and this causes sensor sensitivity to be improved. On the other hand, in the structure, a 0th-order light component fails to be efficiently trapped in the silicon substrate, and therefore it is requested that further improvements be performed and sensor sensitivity be improved.

The present disclosure has been made in view of such a situation, and enables sensor sensitivity to be improved.

### Solutions to Problems

A sensor element in one aspect of the present disclosure includes: a semiconductor layer in which an optical-to-electrical conversion element is formed, the optical-to-electrical conversion element receiving light in a predetermined wavelength range and performing optical-to-electrical conversion; a reflection suppressing part that suppresses reflection of the light, on a first surface serving as a side on which the light enters the semiconductor layer; and a transmission suppressing part that suppresses transmission through the semiconductor layer of the light that has been made incident from the first surface, on a second surface serving as a side that is opposite to the first surface of the semiconductor layer.

An electronic device in one aspect of the present disclosure includes a sensor element that includes: a semiconductor layer in which an optical-to-electrical conversion element is formed, the optical-to-electrical conversion element receiving light in a predetermined wavelength range and performing optical-to-electrical conversion; a reflection suppressing part that suppresses reflection of the light, on a first surface serving as a side on which the light enters the semiconductor layer; and a transmission suppressing part that suppresses transmission through the semiconductor layer of the light that has been made incident from the first surface, on a second surface serving as a side that is opposite to the first surface of the semiconductor layer.

In one aspect of the present disclosure, a reflection suppressing part suppresses reflection of light, on a first surface serving as a side on which light enters a semiconductor layer in which an optical-to-electrical conversion element is formed, the optical-to-electrical conversion element receiving light in a predetermined wavelength range and performing optical-to-electrical conversion. A transmission suppressing part suppresses transmission through the semiconductor layer of the light that has been made incident from the first surface, on a second surface serving as a side that is opposite to the first surface of the semiconductor layer.

### Effects of the Invention

In an aspect of the present disclosure, sensor sensitivity can be improved.

Note that the effect described here is not necessarily restrictive, and any of effects described in the present disclosure may be exhibited.

### BRIEF DESCRIPTION OF DRAWINGS

FIG. 1 is a diagram illustrating a first configuration example according to a first embodiment of a pixel that is provided in a sensor element to which the present technology has been applied.

FIG. 2 is a diagram explaining a pixel having a conventional structure.

FIG. 3 is a sectional view illustrating a configuration example of a solid-state imaging element that includes pixels having the configuration illustrated in FIG. 1.

FIG. 4 is a diagram illustrating a planar layout example of pixels having the configuration illustrated in FIG. 1.

FIG. 5 is a diagram illustrating an example of a circuit configuration of an 8-pixel sharing structure.

FIG. 6 is a diagram illustrating a second configuration example of a pixel according to the first embodiment.

FIG. 7 is a sectional view illustrating a configuration example of a solid-state imaging element that includes pixels having the configuration illustrated in FIG. 6.

FIG. 8 is a diagram illustrating a planar layout example of pixels having the configuration illustrated in FIG. 6.

FIG. 9 is a diagram illustrating a third configuration example of a pixel according to the first embodiment.

FIG. 10 is a sectional view illustrating a configuration example of a solid-state imaging element that includes pixels having the configuration illustrated in FIG. 9.

FIG. 11 is a diagram illustrating a planar layout example of pixels having the configuration illustrated in FIG. 9.

FIG. 12 is a diagram illustrating a fourth configuration example of a pixel according to the first embodiment.

FIG. 13 is a sectional view illustrating a configuration example of a solid-state imaging element that includes pixels having the configuration illustrated in FIG. 12.

FIG. 14 is a diagram illustrating a fifth configuration example according to the first embodiment of a pixel.

FIG. 15 is a diagram explaining shapes of a reflection suppressing part and a transmission suppressing part that are illustrated in FIG. 14.

FIG. 16 is a diagram explaining a variation of the transmission suppressing part.

FIG. 17 is a sectional view illustrating a configuration example of a solid-state imaging element that includes pixels having the configuration illustrated in FIG. 14.

FIG. 18 is a diagram illustrating a planar layout example of pixels having the configuration illustrated in FIG. 14.

FIG. 19 is a diagram illustrating a first configuration example according to a second embodiment of a pixel that is provided in a sensor element to which the present technology is applied.

FIG. 20 is a sectional view illustrating a configuration example of a solid-state imaging element that includes pixels having the configuration illustrated in FIG. 19.

FIG. 21 is a diagram illustrating a second configuration example of a pixel according to the second embodiment.

FIG. 22 is a sectional view illustrating a configuration example of a solid-state imaging element that includes pixels having the configuration illustrated in FIG. 21.

FIG. 23 is a diagram illustrating a third configuration example of a pixel according to the second embodiment.

FIG. 24 is a sectional view illustrating a configuration example of a solid-state imaging element that includes pixels having the configuration illustrated in FIG. 23.

FIG. 25 is a diagram illustrating a fourth configuration example of a pixel according to the second embodiment.

FIG. 26 is a sectional view illustrating a configuration example of a solid-state imaging element that includes pixels having the configuration illustrated in FIG. 25.

FIG. 27 is a diagram illustrating a fifth configuration example of a pixel according to the second embodiment.

FIG. 28 is a sectional view illustrating a configuration example of a solid-state imaging element that includes pixels having the configuration illustrated in FIG. 27.

FIG. 29 is a diagram illustrating a sixth configuration example of a pixel according to the second embodiment.

FIG. 30 is a sectional view illustrating a configuration example of a solid-state imaging element that includes pixels having the configuration illustrated in FIG. 29.

FIG. 31 is a diagram explaining a sensor potential and a vertical transistor.

FIG. 32 is a diagram explaining a pitch size of a diffractive structure.

FIG. 33 is a diagram illustrating an example of the external appearance of an electronic device on which a solid-state imaging element is mounted.

FIG. 34 is a diagram illustrating an example of a circuit configuration of a solid-state imaging element.

FIG. 35 is a block diagram illustrating a configuration example of an imaging apparatus.

FIG. 36 is a diagram illustrating usage examples in which an image sensor is used.

FIG. 37 is a block diagram illustrating an example of a schematic configuration of a vehicle control system.

FIG. 38 is an explanatory diagram illustrating an example of the installation positions of an outside-vehicle information detector and an imaging unit.

FIG. 39 is a diagram illustrating an outline of configuration examples of a stacked type solid-state imaging apparatus to which the technology according to the present disclosure can be applied.

### MODES FOR CARRYING OUT THE INVENTION

Specific embodiments to which the present technology has been applied are described in detail below with reference to the drawings.

<First Configuration Example of Pixel According to First Embodiment>

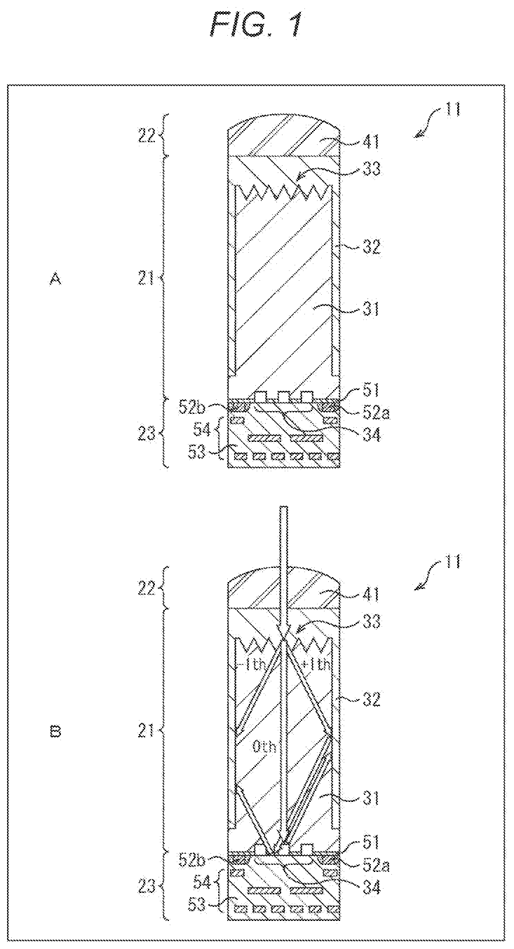

FIG. 1 is a diagram illustrating a first configuration example according to a first embodiment of a pixel that is provided in a sensor element to which the present technology has been applied. A of FIG. 1 illustrates a sectional configuration example of a pixel 11, and B of FIG. 1 schematically illustrates a state where incident light that has entered the pixel 11 is diffracted or reflected.

As illustrated in FIG. 1, in the pixel 11, an on-chip lens layer 22 has been stacked on a light receiving surface side of a sensor substrate 21, and a wiring layer 23 has been stacked on a circuit surface side that faces a direction opposite to the light receiving surface. Stated another way, the pixel 11 has, for example, a configuration in which the present technology has been applied to a reverse-surface irradiation type image sensor in which a circuit board (not illustrated) has been stacked via the wiring layer 23 on a front-surface side in a process of manufacturing a silicon substrate and a reverse-surface side is irradiated with light. Needless to say, the present technology may be applied to a front-surface irradiation type image sensor.

In the sensor substrate 21, a deep trench isolation (DTI) 32 that is an element isolation structure for isolating adjacent pixels 11 from each other has been formed to surround a semiconductor layer 31 in which an optical-to-electrical converter that receives light in a predetermined wavelength range and performs optical-to-electrical conversion is formed. For example, in the DTI 32, an insulator (for example, SiO2) has been embedded into a groove formed by digging in the semiconductor layer 31 from the light receiving surface side. Furthermore, in the example illustrated in FIG. 1, the DTI 32 is formed to have a depth that causes a state where semiconductor layers 31 of adjacent pixels 11 are connected to each other on the circuit surface side of the semiconductor layers 31.

Furthermore, in the pixel 11, a reflection suppressing part 33 that suppresses reflection of light that enters the semiconductor layer 31 is formed on the light receiving surface of the semiconductor layer 31.

The reflection suppressing part 33 includes, for example, an uneven structure formed by providing, at predetermined intervals, a plurality of quadrangular pyramid shapes or reversed quadrangular pyramid shapes that includes a slope having an inclination angle according to a plane index of a crystal surface of a single crystal silicon wafer that configures the semiconductor layer 31. Specifically, the reflection suppressing part 33 includes an uneven structure in which a plane index of a crystal surface of a single crystal silicon wafer is 110 or 111 and an interval between adjacent vertices of a plurality of quadrangular pyramid shapes or reversed quadrangular pyramid shapes is greater than or equal to 200 nm and is less than or equal to 1000 nm.

Then, in the pixel 11, a transmission suppressing part 34 that suppresses transmission through the semiconductor layer 31 of light that has entered the semiconductor layer 31 is formed on the circuit surface of the semiconductor layer 31.

The transmission suppressing part 34 includes an uneven structure that is formed, for example, by digging, at predetermined intervals, a plurality of shallow trench isolations (STIs) that has a recessed shape with respect to the circuit surface of the semiconductor layer 31. Stated another way, the transmission suppressing part 34 is formed in a process that is similar to a process of forming trenches of the DTI 32, but is formed to have a depth that is shallower than a depth of the trenches of the DTI 32. Specifically, the transmission suppressing part 34 includes an uneven structure in which trenches have been dug to have a depth of 100 nm or more and an interval between adjacent trenches is greater than or equal to 100 nm and is less than or equal to 1000 nm.

The on-chip lens layer 22 includes a microlens 41 that condenses, for each of the pixels 11, light that has been applied to the sensor substrate 21. Furthermore, the on-chip lens layer 22 is stacked, for example, on a flat surface that has been flattened by an insulator in a process of embedding the insulator into the DTI 32 from the light receiving surface side of the semiconductor layer 31.

The wiring layer 23 has a configuration in which an optically thin insulating film 51 has been formed on the circuit surface of the semiconductor layer 31, gate electrodes 52a and 52b have been stacked via the insulating film 51, and moreover, a plurality of multilayer interconnections 54 that is insulated from each other by an interlayer insulating film 53 has been formed.

As described above, the pixel 11 has a structure in which the reflection suppressing part 33 is provided on the light receiving surface of the semiconductor layer 31 and the transmission suppressing part 34 is provided on the circuit surface of the semiconductor layer 31. The transmission suppressing part 34 includes an uneven structure that includes a plurality of shallow trenches.

Then, as illustrated in B of FIG. 1, incident light that has entered the semiconductor layer 31 is diffracted by the reflection suppressing part 33, and the uneven structure of the transmission suppressing part 34 suppresses transmission through the semiconductor layer 31 of a 0th-order light component that has advanced straight through the semiconductor layer 31 of the incident light. Furthermore, a 1st-order light component that has been diffracted by the reflection suppressing part 33 of the incident light is reflected by the DTI 32, and is also reflected by the transmission suppressing part 34 of the semiconductor layer 31.

As described above, the pixel 11 can trap incident light that has entered the semiconductor layer 31, by using a combination of the DTI 32 and the transmission suppressing part 34. Stated another way, the pixel 11 can suppress transmission of the incident light through the semiconductor layer 31 to the outside. Therefore, the pixel 11 can improve the efficiency of absorbing, in particular, light ranging from a red wavelength to near infrared rays, even if the semiconductor layer 31 has a limited thickness. As a result, the pixel 11 can remarkably improve sensitivity, quantum efficiency, or the like with respect to the wavelength band described above, and can improve sensor sensitivity.

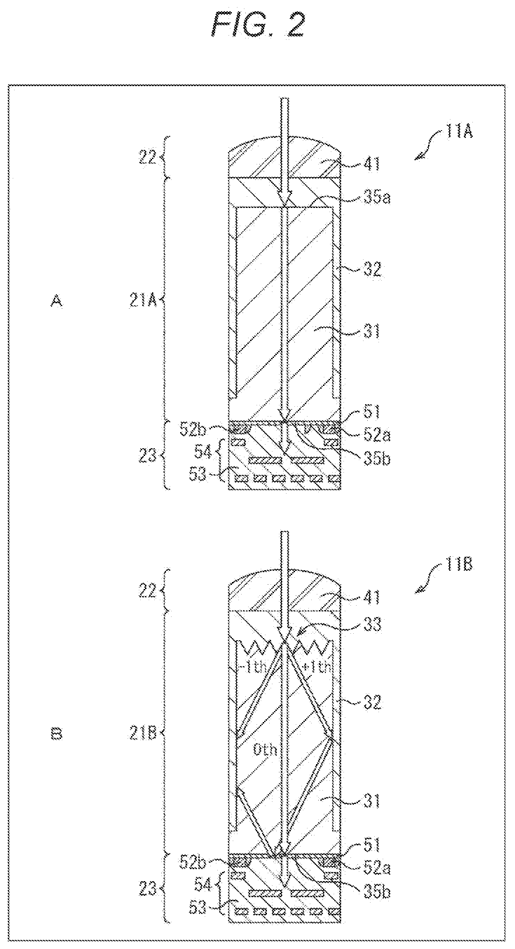

Here, transmission of light in a pixel 11A and a pixel 11B that have a conventional structure is described with reference to FIG. 2.

A of FIG. 2 illustrates the pixel 11A having a structure that includes a sensor substrate 21A in which the reflection suppressing part 33 and the transmission suppressing part 34 are not provided, a flat surface 35a has been formed on the light receiving surface of the semiconductor layer 31, and a flat surface 35b has been formed on the circuit surface of the semiconductor layer 31. In the pixel 11A, incident light that has entered the semiconductor layer 31 is not diffracted by the flat surface 35a, advances straight through the semiconductor layer 31, and is transmitted through the flat surface 35b to the wiring layer 23.

B of FIG. 2 illustrates the pixel 11B having a structure that includes a sensor substrate 21B in which the transmission suppressing part 34 is not provided, the reflection suppressing part 33 is provided on the light receiving surface of the semiconductor layer 31, and the flat surface 35b has been formed on the circuit surface of the semiconductor layer 31. In the pixel 11B, incident light that has entered the semiconductor layer 31 is diffracted by the reflection suppressing part 33, and a 1st-order light component that has been diffracted is totally reflected by an interface of the flat surface 35b, and is trapped in the pixel 11B. On the other hand, a 0th-order light component of diffracted light advances straight through the semiconductor layer 31, and is transmitted through the flat surface 35b to the wiring layer 23.

As described above, in the pixel 11A and the pixel 11B that have a conventional structure, incident light is transmitted through the semiconductor layer 31 to the wiring layer 23, and the incident light fails to be efficiently trapped.

In contrast, as described above with reference to B of FIG. 1, the pixel 11 can remarkably improve an effect of a trapping structure (a light trapping pixel), and can efficiently trap incident light by suppressing transmission of a 0th-order light component of the incident light to the wiring layer 23. Therefore, the pixel 11 can maximize sensitivity or quantum efficiency with respect to near infrared rays by using a limited thickness of the semiconductor layer 31, and can improve sensor sensitivity in comparison with the pixel 11A and the pixel 11B.

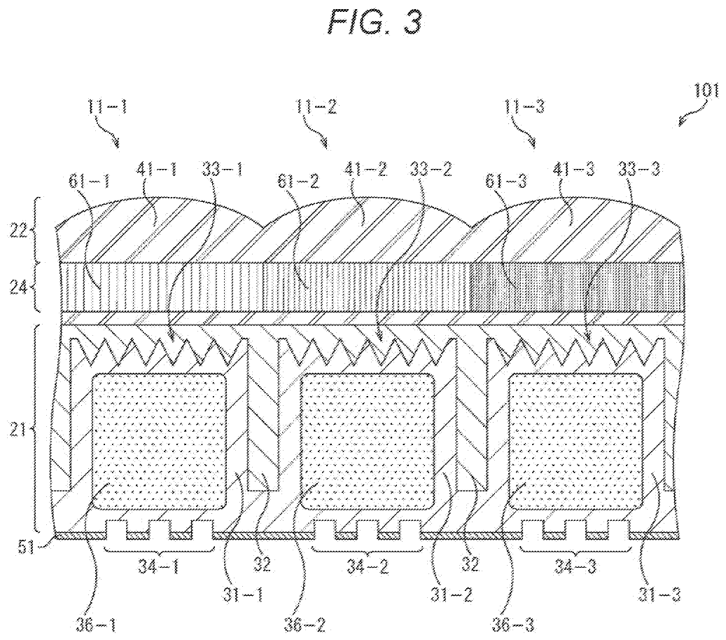

A configuration example of a solid-state imaging element 101 that is a sensor element in which a plurality of pixels 11 has been arranged in an array shape is described with reference to FIG. 3. FIG. 3 illustrates sectional configurations of three pixels 11-1 to 11-3. Note that, in FIG. 3, the wiring layer 23 illustrated in FIG. 1 is omitted.

As illustrated in FIG. 3, in the solid-state imaging element 101, a filter layer 24 has been stacked between the sensor substrate 21 and the on-chip lens layer 22. Note that a flattened film may be formed between the sensor substrate 21 and the filter layer 24.

In the filter layer 24, color filters 61-1 to 61-3 through which light in a wavelength range of light reception of the pixels 11-1 to 11-3 is selectively transmitted have been respectively disposed for the pixels 11-1 to 11-3. For example, in the filter lay 24, a visible color filter through which a wavelength range (for example, a wavelength ranging from 400 nm to 700 nm) of visible light is transmitted is used. Then, light in a red wavelength range is transmitted through the color filter 61-1, light in a green wavelength range is transmitted through the color filter 61-2, and light in a blue wavelength range is transmitted through the color filter 61-3. Furthermore, rather than transmitting light in a wavelength range of visible light, the filter layer 24 may employ, for example, a configuration in which an infrared (IR) transmission type filter that cuts off light in a wavelength range of visible light and through which a wavelength range (for example, a wavelength of 700 nm to 1100 nm) of near infrared rays is transmitted is disposed.

Furthermore, in the solid-state imaging element 101, optical-to-electrical converters 36-1 to 36-3 have been formed in semiconductor layers 31-1 to 31-3 for the respective pixels 11-1 to 11-3. The optical-to-electrical converter 36-1 receives light that has been transmitted through the color filter 61-1, and performs optical-to-electrical conversion on the light. The optical-to-electrical converter 36-2 receives light that has been transmitted through the color filter 61-2, and performs optical-to-electrical conversion on the light. The optical-to-electrical converter 36-3 receives light that has been transmitted through the color filter 61-3, and performs optical-to-electrical conversion on the light.

Then, in the solid-state imaging element 101, transmission suppressing parts 34-1 to 34-3 are provided on circuit surfaces of the respective semiconductor layers 31-1 to 31-3 in the pixels 11-1 to 11-3.

In the solid-state imaging element 101 configured as described above, the pixels 11-1 to 11-3 can efficiently perform optical-to-electrical conversion on rays of light in respective wavelength ranges, and an image having a higher sensitivity can be captured.

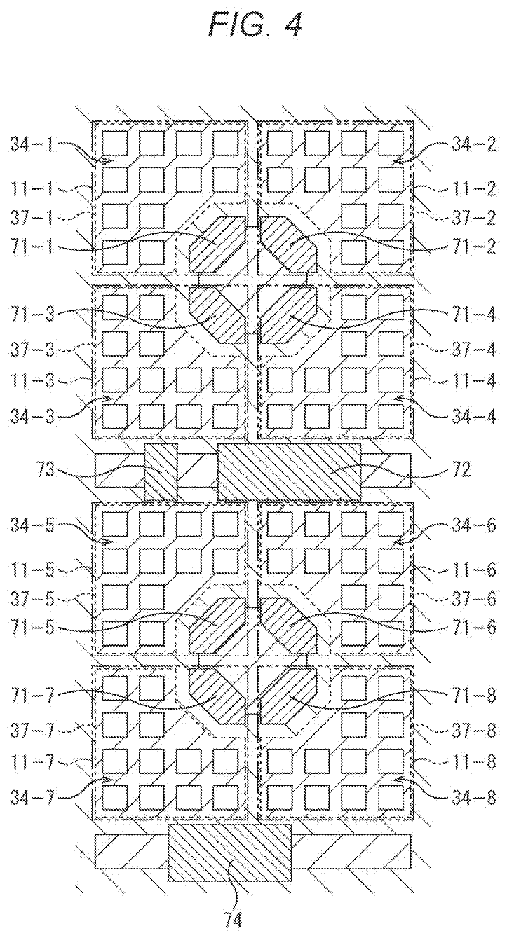

FIG. 4 illustrates an example of a planar layout of pixels 11 in the solid-state imaging element 101.

For example, the solid-state imaging element 101 can employ a pixel sharing structure in which a predetermined number of pixels 11 share a transistor. FIG. 4 is a schematic diagram of a pixel sharing structure including eight pixels 11-1 to 11-8 that have been arranged in a 2×4 shape.

As illustrated in FIG. 4, in the pixel sharing structure, transfer transistors 71-1 to 71-8 are respectively provided for the pixels 11-1 to 11-8. Furthermore, in the pixel sharing structure, one amplification transistor 72, one selection transistor 73, and one reset transistor 74 that are shared are provided for the pixels 11-1 to 11-8. Then, a transistor that is used to drive these pixels 11-1 to 11-8 is disposed on a circuit surface side of a semiconductor layers 31.

Accordingly, transmission suppressing parts 34-1 to 34-8 that are provided on the circuit surfaces of the semiconductor layers 31 are formed in effective pixel regions 37-1 to 37-8, as illustrated, for the respective pixels 11-1 to 11-8, when the solid-state imaging element 101 is viewed from the circuit surface side in a plan view. Here, the effective pixel regions 37-1 to 37-8 are regions obtained by removing, from respective regions of the pixels 11-1 to 11-8, a range in which the transfer transistors 71-1 to 71-8, the amplification transistor 72, the selection transistor 73, and the reset transistor 74 are disposed.

For example, the effective pixel region 37-1 of the pixel 11-1 is a region in which the optical-to-electrical converter 36-1 illustrated in FIG. 3 is disposed, and is a region obtained by removing a range in which the transfer transistor 71-1 is disposed, when viewed from the circuit surface side in a plan view. Furthermore, the effective pixel regions 37-2 to 37-8 of the pixels 11-2 to 11-8 are regions that are similar to the region described above.

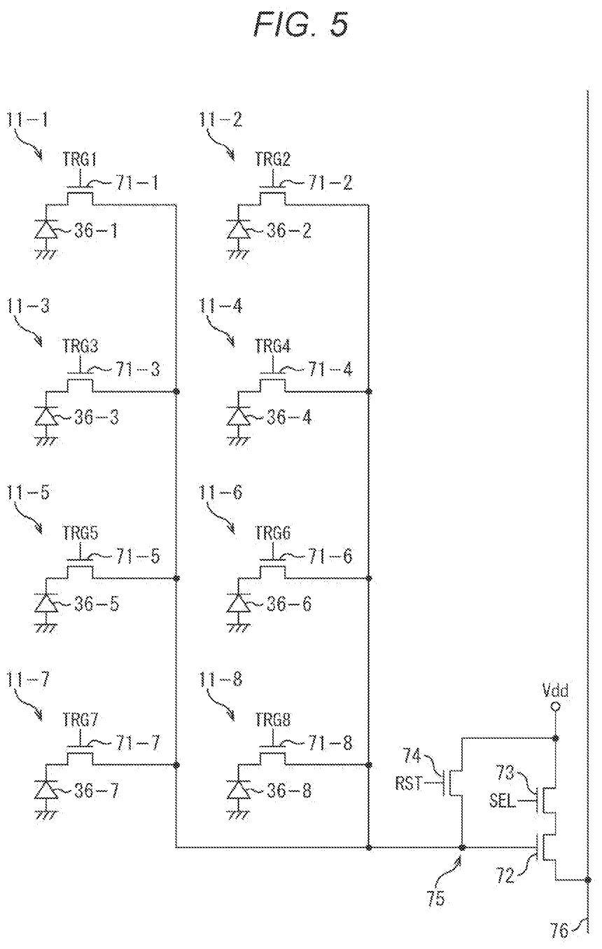

FIG. 5 is a circuit diagram of the pixel sharing structure illustrated in FIG. 4 that includes the pixels 11-1 to 11-8.

As illustrated in FIG. 5, in the pixels 11-1 to 11-8, the optical-to-electrical converters 36-1 to 36-8 are respectively connected to an FD unit 75 via the transfer transistors 71-1 to 71-8, and the FD unit 75 is shared by the pixels 11-1 to 11-8. Then, the FD unit 75 is connected to a gate electrode of the amplification transistor 72. A source of the amplification transistor 72 is connected to a vertical signal line 76, and a drain of the amplification transistor 72 is connected to a Vdd power supply via the selection transistor 73.

Furthermore, the FD unit 75 is connected to the Vdd power supply via the reset transistor 74.

The pixels 11-1 to 11-8 can employ a pixel sharing structure having such a circuit configuration. Note that a pixel sharing structure having a circuit configuration that is similar to the circuit configuration illustrated in FIG. 5 can be employed in the respective configuration examples described below.

<Second Configuration Example of Pixel According to First Embodiment>

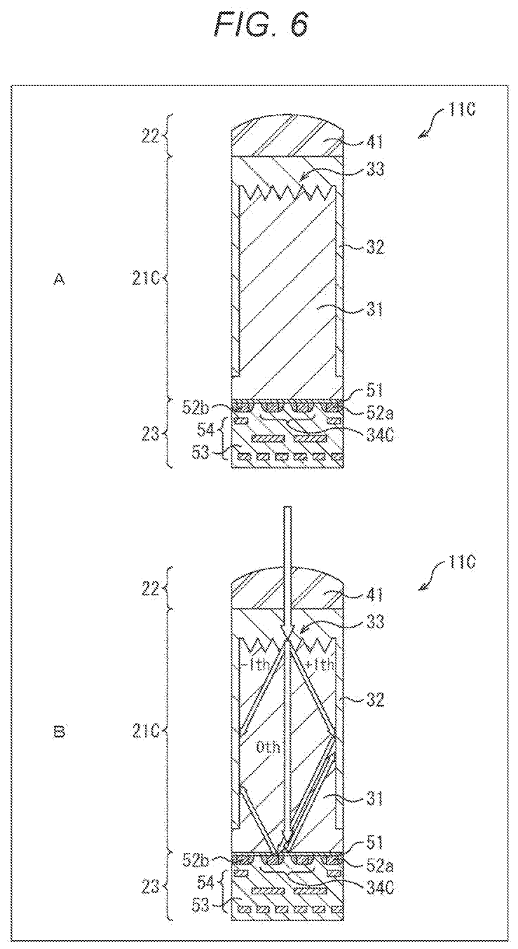

FIG. 6 is a diagram illustrating a second configuration example according to the first embodiment of a pixel that is provided in a sensor element to which the present technology has been applied. A of FIG. 6 illustrates a sectional configuration example of a pixel 11C, and B of FIG. 6 schematically illustrates a state where incident light that has entered the pixel 11C is diffracted or reflected. Note that, in regard to the configuration illustrated in FIG. 6 of the pixel 11C, the same reference signs are used in a configuration that is common to the configuration of the pixel 11 of FIG. 1, and the detailed description thereof is omitted.

As illustrated in FIG. 6, in the pixel 11C, similarly to the pixel 11 of FIG. 1, an on-chip lens layer 22 has been stacked on a light receiving surface side of a sensor substrate 21C, and a wiring layer 23 has been stacked on a circuit surface side of the sensor substrate 21C. Furthermore, in the pixel 11C, similarly to the pixel 11 of FIG. 1, a reflection suppressing part 33 has been formed on a light receiving surface of a semiconductor layer 31.

On the other hand, in the sensor substrate 21C of the pixel 11C, a transmission suppressing part 34C provided on a circuit surface of the semiconductor layer 31 has a configuration that is different from a configuration of the transmission suppressing part 34 of the pixel 11 of FIG. 1.

Stated another way, the transmission suppressing part 34C includes, for example, an uneven structure formed by disposing, at predetermined intervals, a plurality of dummy electrodes that has a protruding shape with respect to the circuit surface of the semiconductor layer 31. For example, a dummy electrode included in the transmission suppressing part 34C can include polysilicon similarly to the gate electrode 52, and is stacked on the circuit surface of the semiconductor layer 31 via an insulating film 51. Furthermore, this dummy electrode electrically floats, or is fixed at a ground potential.

Specifically, the transmission suppressing part 34C includes an uneven structure in which dummy electrodes have been formed to have a height of 100 nm or more and an interval between adjacent dummy electrodes is greater than or equal to 100 nm and is less than or equal to 1000 nm.

As described above, the pixel 11C has a structure in which the reflection suppressing part 33 is provided on the light receiving surface of the semiconductor layer 31 and the transmission suppressing part 34C is provided on the circuit surface of the semiconductor layer 31. The transmission suppressing part 34C includes an uneven structure that includes a plurality of dummy electrodes. Then, the transmission suppressing part 34C can suppress transmission through the semiconductor layer 31 to the outside of a 0th-order light component that has advanced straight through the semiconductor layer 31, similarly to the transmission suppressing part 34 of FIG. 1.

Accordingly, the pixel 11C can trap incident light that has entered the semiconductor layer 31, by using a combination of a DTI 32 and the transmission suppressing part 34C, similarly to the pixel 11 of FIG. 1, and as a result, sensor sensitivity can be improved.

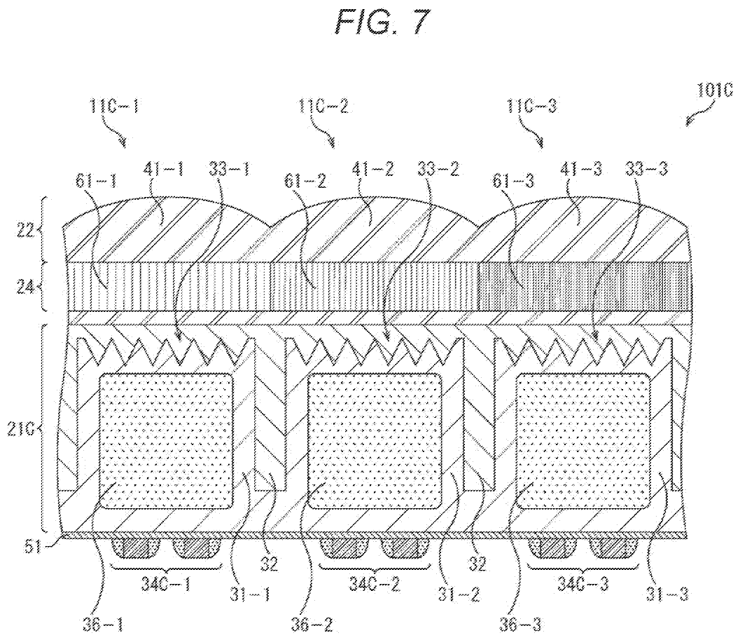

FIG. 7 illustrates sectional configurations of three pixels 11C-1 to 11C-3 in a solid-state imaging element 101C in which a plurality of pixels 11C has been arranged in an array shape, similarly to FIG. 3. Note that, in regard to the configuration illustrated in FIG. 7 of the solid-state imaging element 101C, the same reference signs are used in a configuration that is common to the configuration of the solid-state imaging element 101 of FIG. 3, and the detailed description thereof is omitted.

As illustrated in FIG. 7, in the solid-state imaging element 101C, transmission suppressing parts 34C-1 to 34C-3 are provided on circuit surfaces of respective semiconductor layers 31-1 to 31-3 in the pixels 11C-1 to 11C-3.

In the solid-state imaging element 101C configured as described above, the pixels 11C-1 to 11C-3 can efficiently perform optical-to-electrical conversion on rays of light in respective wavelength ranges, and an image having a higher sensitivity can be captured.

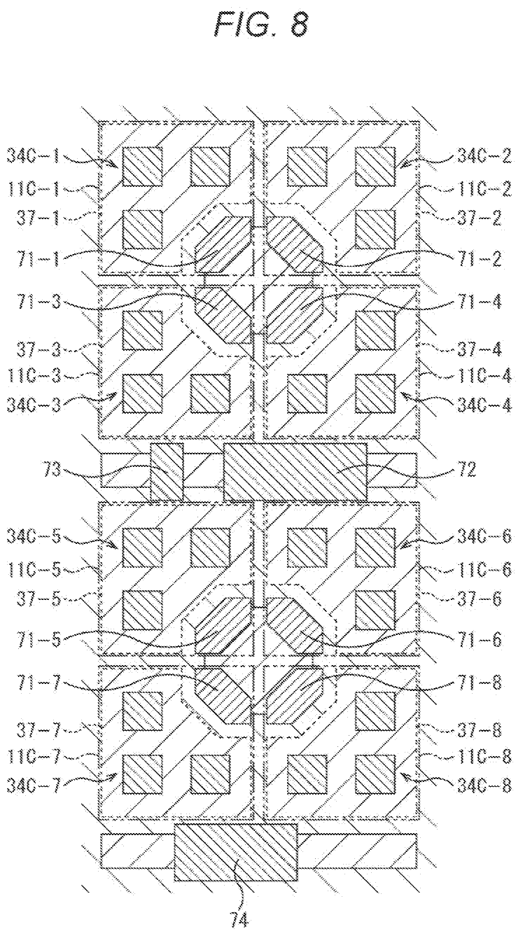

FIG. 8 illustrates an example of a planar layout of eight pixels 11C-1 to 11C-8 in the solid-state imaging element 101C, similarly to FIG. 4. Note that, in regard to the configurations illustrated in FIG. 8 of the pixels 11C-1 to 11C-8, the same reference signs are used in configurations that are common to the configurations of the pixels 11-1 to 11-8 of FIG. 4, and the detailed description thereof is omitted.

As illustrated in FIG. 8, transmission suppressing parts 34C-1 to 34C-8 that are provided on circuit surfaces of semiconductor layers 31 are formed in effective pixel regions 37-1 to 37-8, as illustrated, for the respective pixels 11C-1 to 11C-8, when the solid-state imaging element 101C is viewed from a circuit surface side in a plan view.

<Third Configuration Example of Pixel According to First Embodiment>

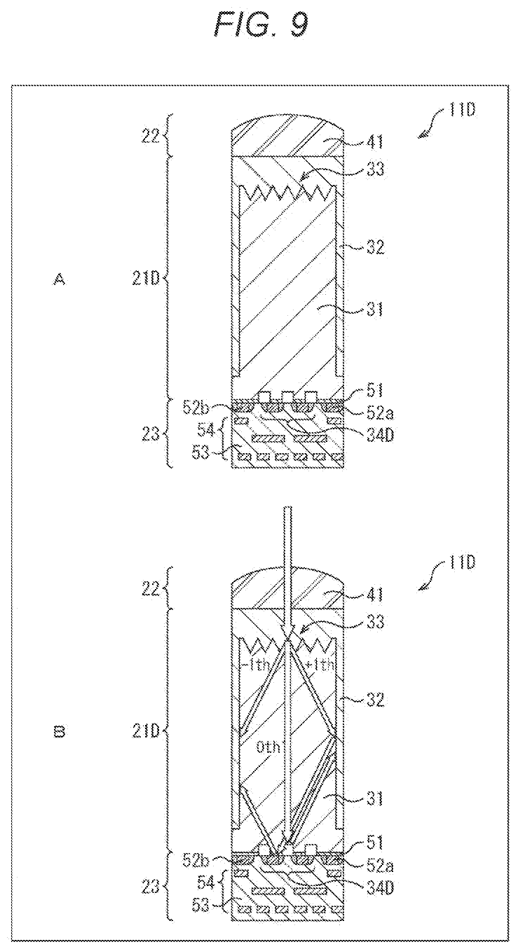

FIG. 9 is a diagram illustrating a third configuration example according to the first embodiment of a pixel that is provided in a sensor element to which the present technology has been applied. A of FIG. 9 illustrates a sectional configuration example of a pixel 11D, and B of FIG. 9 schematically illustrates a state where incident light that has entered the pixel 11D is diffracted or reflected. Note that, in regard to the configuration illustrated in FIG. 9 of the pixel 11D, the same reference signs are used in a configuration that is common to the configuration of the pixel 11 of FIG. 1, and the detailed description thereof is omitted.

As illustrated in FIG. 9, in the pixel 11D, similarly to the pixel 11 of FIG. 1, an on-chip lens layer 22 has been stacked on a light receiving surface side of a sensor substrate 21D, and a wiring layer 23 has been stacked on a circuit surface side of the sensor substrate 21D. Furthermore, in the pixel 11D, similarly to the pixel 11 of FIG. 1, a reflection suppressing part 33 has been formed on a light receiving surface of a semiconductor layer 31.

On the other hand, in the sensor substrate 21D of the pixel 11D, a transmission suppressing part 34D provided on a circuit surface of the semiconductor layer 31 has a configuration that is different from a configuration of the transmission suppressing part 34 of the pixel 11 of FIG. 1.

Stated another way, the transmission suppressing part 34D includes, for example, a combination of an uneven structure formed by digging, at predetermined intervals, a plurality of shallow trenches having a recessed shape with respect to the circuit surface of the semiconductor layer 31 and an uneven structure formed by disposing, at predetermined intervals, a plurality of dummy electrodes having a protruding shape with respect to the circuit surface of the semiconductor layer 31. Stated another way, the transmission suppressing part 34D has a configuration in which the transmission suppressing part 34 illustrated in FIG. 1 is combined with the transmission suppressing part 34C illustrated in FIG. 6.

Specifically, the transmission suppressing part 34D includes an uneven structure that includes trenches that have been dug to have a depth of 100 nm or more and for which an interval between adjacent trenches is greater than or equal to 100 nm and is less than or equal to 1000 nm, and dummy electrodes that have been formed to have a height of 100 nm or more and for which an interval between adjacent dummy electrodes is greater than or equal to 100 nm and is less than or equal to 1000 nm. Furthermore, this dummy electrode is stacked on the circuit surface of the semiconductor layer 31 via an insulating film 51, and electrically floats or is fixed at a ground potential.

As described above, the pixel 11D has a structure in which the reflection suppressing part 33 is provided on the light receiving surface of the semiconductor layer 31 and the transmission suppressing part 34D is provided on the circuit surface of the semiconductor layer 31. The transmission suppressing part 34D includes an uneven structure that includes a plurality of shallow trenches and a plurality of dummy electrodes. Then, the transmission suppressing part 34D can suppress transmission through the semiconductor layer 31 to the outside of a 0th-order light component that has advanced straight through the semiconductor layer 31, similarly to the transmission suppressing part 34 of FIG. 1 and the transmission suppressing part 34C of FIG. 6.

Accordingly, the pixel 11D can trap incident light that has entered the semiconductor layer 31, by using a combination of a DTI 32 and the transmission suppressing part 34D, similarly to the pixel 11 of FIG. 1, and as a result, sensor sensitivity can be improved.

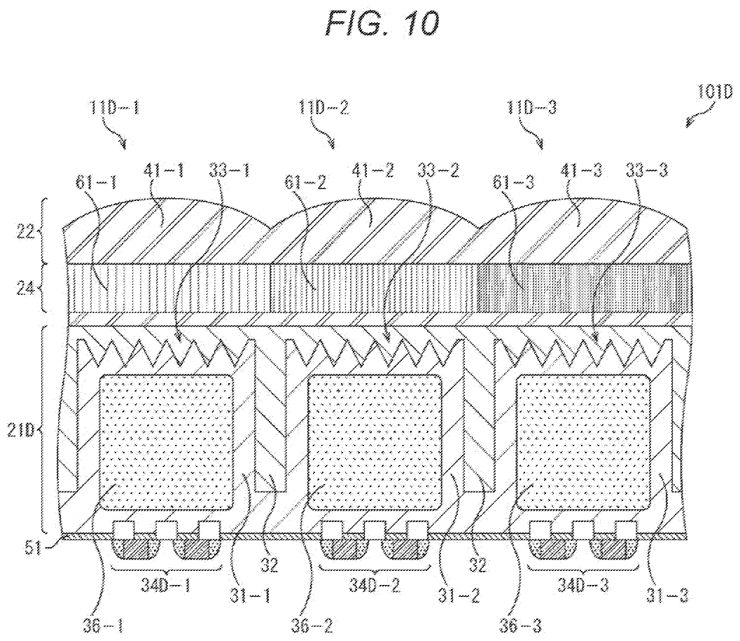

FIG. 10 illustrates sectional configurations of three pixels 11D-1 to 11D-3 in a solid-state imaging element 101D in which a plurality of pixels 11D has been arranged in an array shape, similarly to FIG. 3. Note that, in regard to the configuration illustrated in FIG. 10 of the solid-state imaging element 101D, the same reference signs are used in a configuration that is common to the configuration of the solid-state imaging element 101 of FIG. 3, and the detailed description thereof is omitted.

As illustrated in FIG. 10, in the solid-state imaging element 101D, transmission suppressing parts 34D-1 to 34D-3 are provided on circuit surfaces of respective semiconductor layers 31-1 to 31-3 in the pixels 11D-1 to 11D-3.

In the solid-state imaging element 101D configured as described above, the pixels 11D-1 to 11D-3 can efficiently perform optical-to-electrical conversion on rays of light in respective wavelength ranges, and an image having a higher sensitivity can be captured.

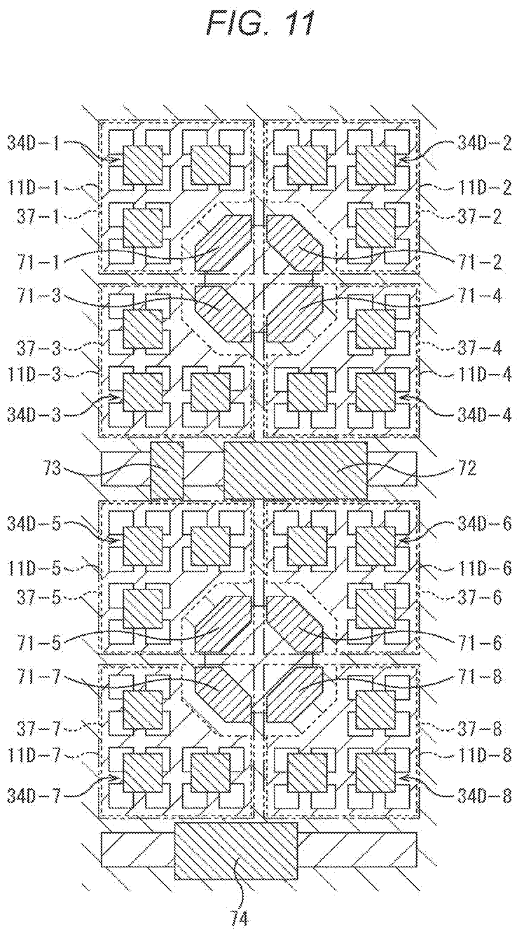

FIG. 11 illustrates an example of a planar layout of eight pixels 11D-1 to 11D-8 in the solid-state imaging element 101D, similarly to FIG. 4. Note that, in regard to the configurations illustrated in FIG. 11 of the pixels 11D-1 to 11D-8, the same reference signs are used in configurations that are common to the configurations of the pixels 11-1 to 11-8 of FIG. 4, and the detailed description thereof is omitted.

As illustrated in FIG. 11, transmission suppressing parts 34D-1 to 34D-8 that are provided on circuit surfaces of semiconductor layers 31 are formed in effective pixel regions 37-1 to 37-8, as illustrated, for the respective pixels 11D-1 to 11D-8, when the solid-state imaging element 101D is viewed from the circuit surface side in a plan view.

<Fourth Configuration Example of Pixel According to First Embodiment>

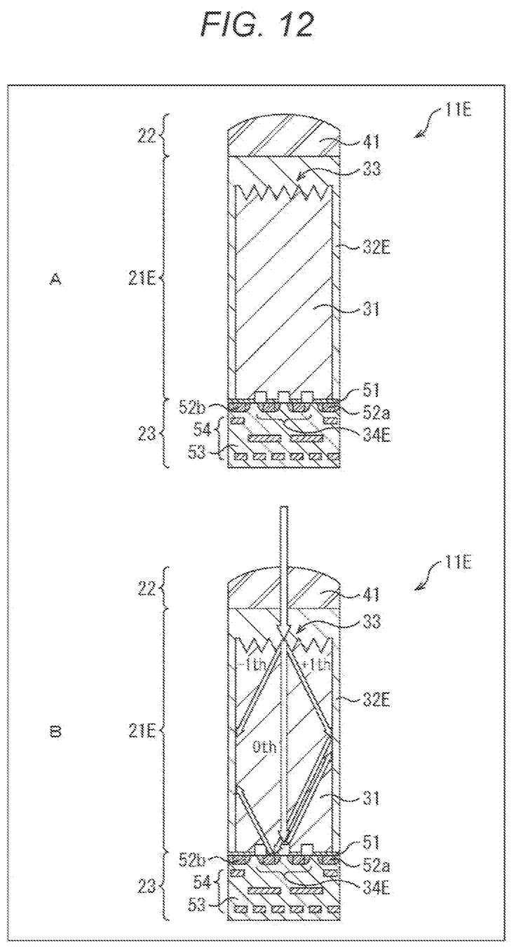

FIG. 12 is a diagram illustrating a fourth configuration example according to the first embodiment of a pixel that is provided in a sensor element to which the present technology has been applied. A of FIG. 12 illustrates a sectional configuration example of a pixel 11E, and B of FIG. 12 schematically illustrates a state where incident light that has entered the pixel 11E is diffracted or reflected. Note that, in regard to the configuration illustrated in FIG. 12 of the pixel 11E, the same reference signs are used in a configuration that is common to the configuration of the pixel 11 of FIG. 1, and the detailed description thereof is omitted.

As illustrated in FIG. 12, in the pixel 11E, similarly to the pixel 11 of FIG. 1, an on-chip lens layer 22 has been stacked on a light receiving surface side of a sensor substrate 21E, and a wiring layer 23 has been stacked on a circuit surface side of the sensor substrate 21E. Furthermore, in the pixel 11E, similarly to the pixel 11 of FIG. 1, a reflection suppressing part 33 has been formed on a light receiving surface of a semiconductor layer 31.

Furthermore, in the pixel 11E, a transmission suppressing part 34E that is provided on a circuit surface of the semiconductor layer 31 includes an uneven structure that includes a plurality of shallow trenches and a plurality of dummy electrodes, similarly to the transmission suppressing part 34D of FIG. 9. Therefore, the pixel 11E can suppress transmission through the semiconductor layer 31 to the outside of a 0th-order light component that has advanced straight through the semiconductor layer 31, similarly to the pixel 11D of FIG. 9.

Moreover, in the sensor substrate 21E of the pixel 11E, a DTI 32E that isolates the semiconductor layer 31 has a configuration that is different from a configuration of the DTI 32 of the pixel 11 of FIG. 1.

Stated another way, in the pixel 11 of FIG. 1, the DTI 32 has been formed in such a way that semiconductor layers 31 of adjacent pixels 11 are connected to each other on the circuit surface side of the semiconductor layers 31. In contrast, in the pixel 11E, the DTI 32E has a penetrating structure that causes semiconductor layers 31 of adjacent pixels 11 to be completely isolated from each other.

As described above, the pixel 11E has a structure in which the reflection suppressing part 33 is provided on the light receiving surface of the semiconductor layer 31 and the transmission suppressing part 34E is provided on the circuit surface of the semiconductor layer 31. The transmission suppressing part 34E includes an uneven structure that includes a plurality of shallow trenches and a plurality of dummy electrodes. Moreover, in the pixel 11E, the DTI 32E has a penetrating structure.

Therefore, the pixel 11E can reliably prevent the leakage of light to an adjacent pixel 11E, by using the DTI 32E having a penetrating structure. Accordingly, the pixel 11E can more reliably trap incident light that has entered the semiconductor layer 31, by using a combination of the DTI 32E and the transmission suppressing part 34E, and as a result, sensor sensitivity can be further improved.

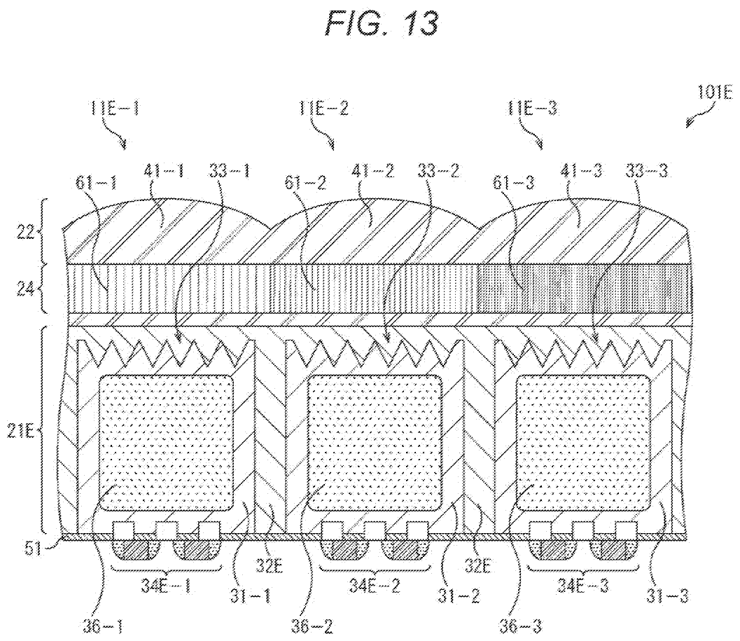

FIG. 13 illustrates sectional configurations of three pixels 11E-1 to 11E-3 in a solid-state imaging element 101E in which a plurality of pixels 11E has been arranged in an array shape, similarly to FIG. 3. Note that, in regard to the configuration illustrated in FIG. 13 of the solid-state imaging element 101E, the same reference signs are used in a configuration that is common to the configuration of the solid-state imaging element 101 of FIG. 3, and the detailed description thereof is omitted.

As illustrated in FIG. 13, in the solid-state imaging element 101E, transmission suppressing parts 34E-1 to 34E-3 are provided on circuit surfaces of respective semiconductor layers 31-1 to 31-3 in the pixels 11E-1 to 11E-3. Then, DTIs 32E having a penetrating structure completely isolate the pixels 11E-1 to 11E-3 from each other.

In the solid-state imaging element 101E configured as described above, the pixels 11E-1 to 11E-3 can efficiently perform optical-to-electrical conversion on rays of light in respective wavelength ranges, and an image having a higher sensitivity can be captured.

Note that a planar layout of the pixels 11E in the solid-state imaging element 101E is similar to the planar layout illustrated in FIG. 11 of the pixels 11D in the solid-state imaging element 101D, and the illustration and description thereof are omitted.

<Fifth Configuration Example of Pixel According to First Embodiment>

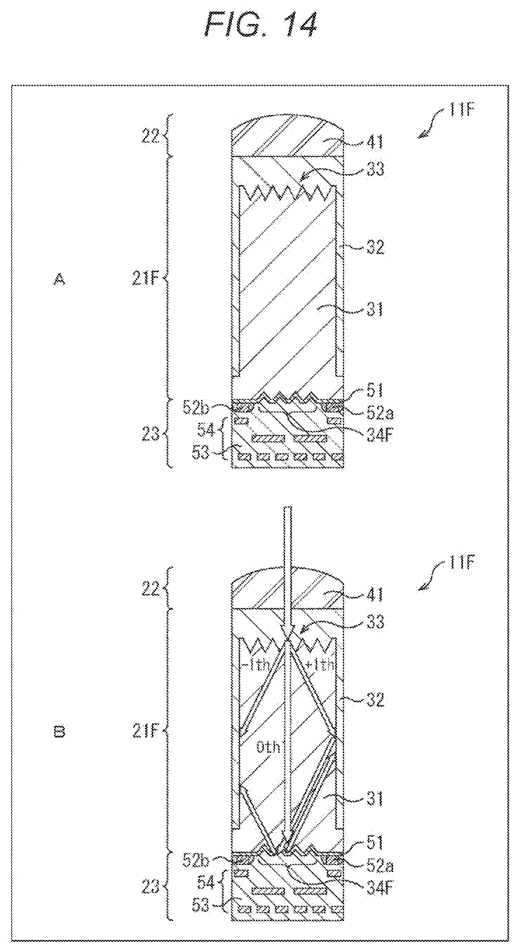

FIG. 14 is a diagram illustrating a fifth configuration example according to the first embodiment of a pixel that is provided in a sensor element to which the present technology has been applied. A of FIG. 14 illustrates a sectional configuration example of a pixel 11F, and B of FIG. 14 schematically illustrates a state where incident light that has entered the pixel 11F is diffracted or reflected. Note that, in regard to the configuration illustrated in FIG. 14 of the pixel 11F, the same reference signs are used in a configuration that is common to the configuration of the pixel 11 of FIG. 1, and the detailed description thereof is omitted.

As illustrated in FIG. 14, in the pixel 11F, similarly to the pixel 11 of FIG. 1, an on-chip lens layer 22 has been stacked on a light receiving surface side of a sensor substrate 21F, and a wiring layer 23 has been stacked on a circuit surface side of the sensor substrate 21F. Furthermore, in the pixel 11F, similarly to the pixel 11 of FIG. 1, a reflection suppressing part 33 has been formed on a light receiving surface of a semiconductor layer 31.

On the other hand, in the pixel 11F, a transmission suppressing part 34F that is provided on a circuit surface of the semiconductor layer 31 in the sensor substrate 21F has a configuration that is different from a configuration of the transmission suppressing part 34 of the pixel 11 of FIG. 1.

Stated another way, the transmission suppressing part 34F includes, for example, an uneven structure formed by providing, at predetermined intervals, a plurality of quadrangular pyramid shapes or reversed quadrangular pyramid shapes that includes a slope having an inclination angle according to a plane index of a crystal surface of a single crystal silicon wafer that configures the semiconductor layer 31, similarly to the reflection suppressing part 33. Specifically, the transmission suppressing part 34F includes an uneven structure in which a plane index of a crystal surface of a single crystal silicon wafer is 110 or 111 and an interval between adjacent vertices of a plurality of quadrangular pyramid shapes or reversed quadrangular pyramid shapes is greater than or equal to 200 nm and is less than or equal to 1000 nm.

For example, the pixel 11F can employ a combination in which the reflection suppressing part 33 is formed in such a way that a plane index of a crystal surface of a single crystal silicon wafer is 111 and the transmission suppressing part 34F is formed in such a way that a plane index of a crystal surface of a single crystal silicon wafer is 110. Needless to say, respective plane indices may be inverted. The reflection suppressing part 33 may be formed in such a way that a plane index of a crystal surface of a single crystal silicon wafer is 110, and the transmission suppressing part 34F may be formed in such a way that a plane index of a crystal surface of a single crystal silicon wafer is 111.

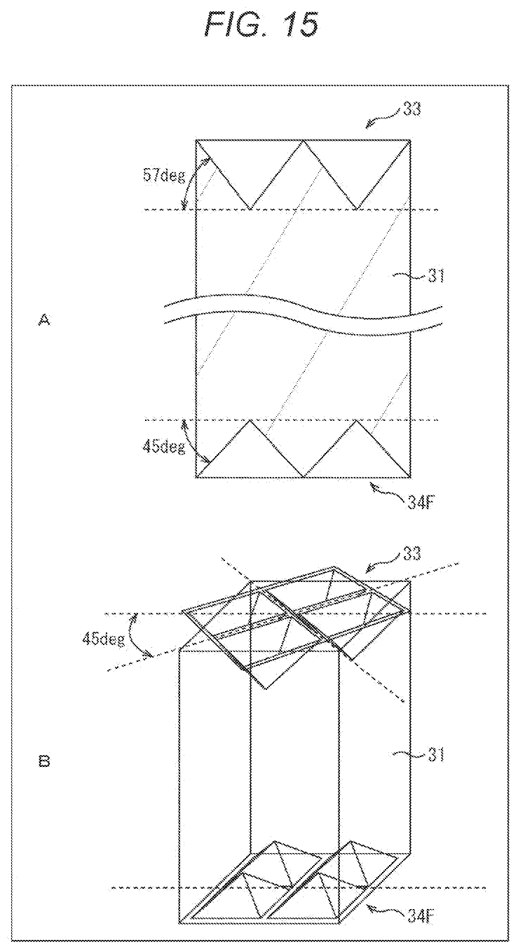

Here, shapes of the reflection suppressing part 33 and the transmission suppressing part 34F are described with reference to FIG. 15. A of FIG. 15 is a sectional schematic diagram, and B of FIG. 15 is a stereoscopic schematic diagram.

FIG. 15 illustrates a configuration example in which the reflection suppressing part 33 and the transmission suppressing part 34F include four reversed quadrangular pyramid shapes.

As illustrated in A of FIG. 15, for example, an angle of a slope that configures an uneven structure of the reflection suppressing part 33 is 57°, and an angle of a slope that configures the uneven structure of the transmission suppressing part 34F is 45°. Furthermore, as illustrated in B of FIG. 15, an orientation of the uneven structure of the reflection suppressing part 33 is relatively offset by 450 with respect to an orientation of the uneven structure of the transmission suppressing part 34F.

Note that, in each of the reflection suppressing part 33 and the transmission suppressing part 34F, the number of quadrangular pyramid shapes or reversed quadrangular pyramid shapes is not limited to the example illustrated in FIG. 15.

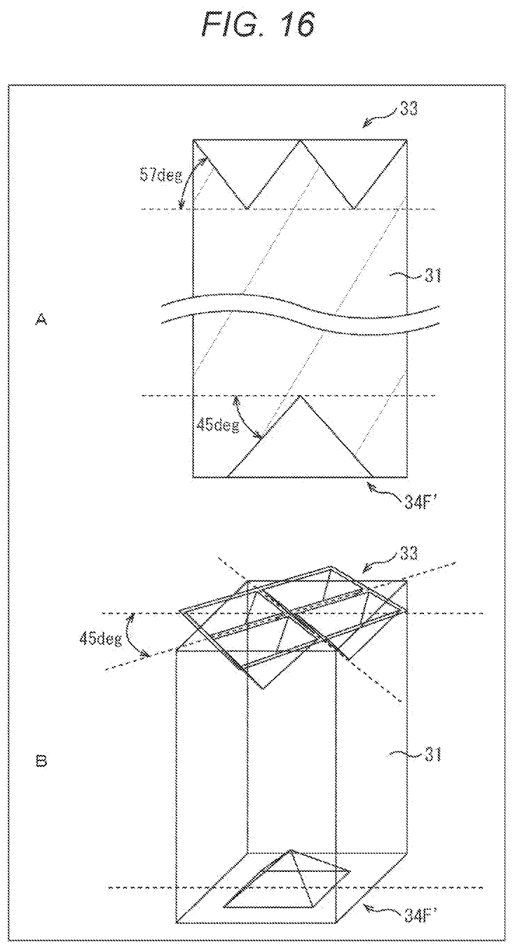

For example, as in a variation illustrated in FIG. 16, a transmission suppressing part 34F′ may include one quadrangular pyramid shape.

As described above, the pixel 11F has a structure in which the reflection suppressing part 33 is provided on the light receiving surface of the semiconductor layer 31 and the transmission suppressing part 34F is provided on the circuit surface of the semiconductor layer 31. The transmission suppressing part 34F includes an uneven structure formed by providing a plurality of quadrangular pyramid shapes or reversed quadrangular pyramid shapes at predetermined intervals. Then, the transmission suppressing part 34F can suppress transmission through the semiconductor layer 31 to the outside of a 0th-order light component that has advanced straight through the semiconductor layer 31, similarly to the transmission suppressing part 34 of FIG. 1.

Accordingly, the pixel 11F can trap incident light that has entered the semiconductor layer 31, by using a combination of a DTI 32 and the transmission suppressing part 34F, similarly to the pixel 11 of FIG. 1, and as a result, sensor sensitivity can be improved.

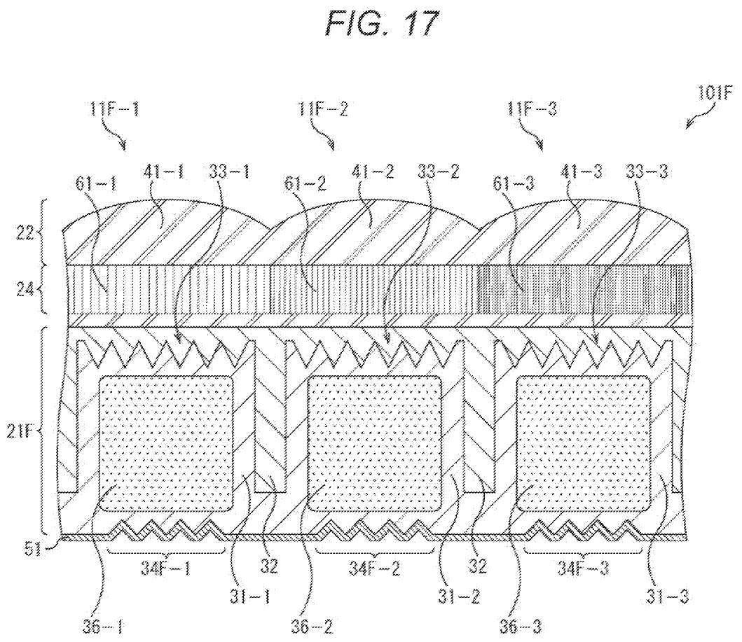

FIG. 17 illustrates sectional configurations of three pixels 11F-1 to 11F-3 in a solid-state imaging element 101F in which a plurality of pixels 11F has been arranged in an array shape, similarly to FIG. 3. Note that, in regard to the configuration illustrated in FIG. 17 of the solid-state imaging element 101F, the same reference signs are used in a configuration that is common to the configuration of the solid-state imaging element 101 of FIG. 3, and the detailed description thereof is omitted.

As illustrated in FIG. 17, in the solid-state imaging element 101F, transmission suppressing parts 34F-1 to 34F-3 are provided on circuit surfaces of respective semiconductor layers 31-1 to 31-3 in the pixels 11F-1 to 11F-3.

In the solid-state imaging element 101F configured as described above, the pixels 11F-1 to 11F-3 can efficiently perform optical-to-electrical conversion on rays of light in respective wavelength ranges, and an image having a higher sensitivity can be captured.

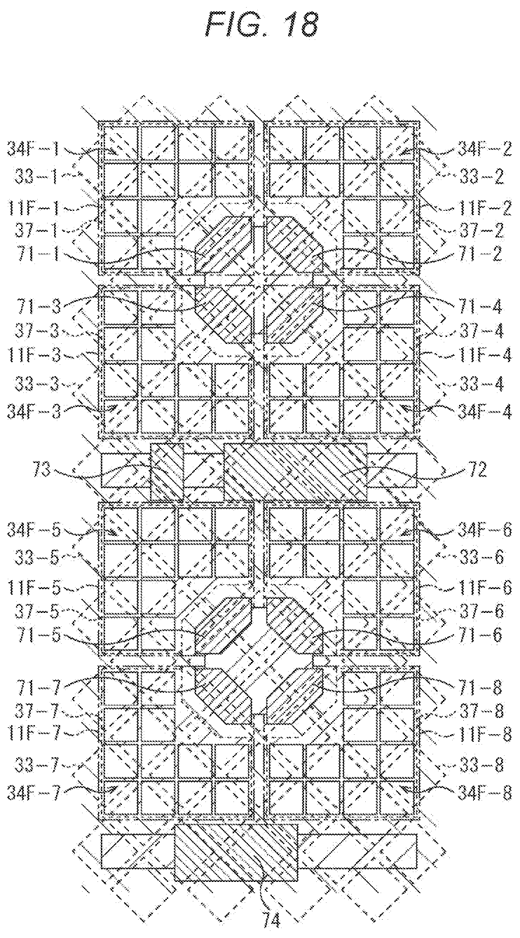

FIG. 18 illustrates an example of a planar layout of eight pixels 11F-1 to 11F-8 in the solid-state imaging element 101F, similarly to FIG. 4. Note that, in regard to the configurations illustrated in FIG. 18 of the pixels 11F-1 to 11F-8, the same reference signs are used in configurations that are common to the configurations of the pixels 11-1 to 11-8 of FIG. 4, and the detailed description thereof is omitted.

As illustrated in FIG. 18, transmission suppressing parts 34F-1 to 34F-8 that are provided on circuit surfaces of semiconductor layers 31 are formed in effective pixel regions 37-1 to 37-8, as illustrated, for the respective pixels 11F-1 to 11F-8, when the solid-state imaging element 101F is viewed from the circuit surface side in a plan view. Furthermore, as described above with reference to FIG. 15, an orientation of an uneven structure of reflection suppressing parts 33-1 to 33-9 is relatively offset by 450 with respect to an orientation of an uneven structure of the transmission suppressing parts 34F-1 to 34F-8.

<First Configuration Example of Pixel According to Second Embodiment>

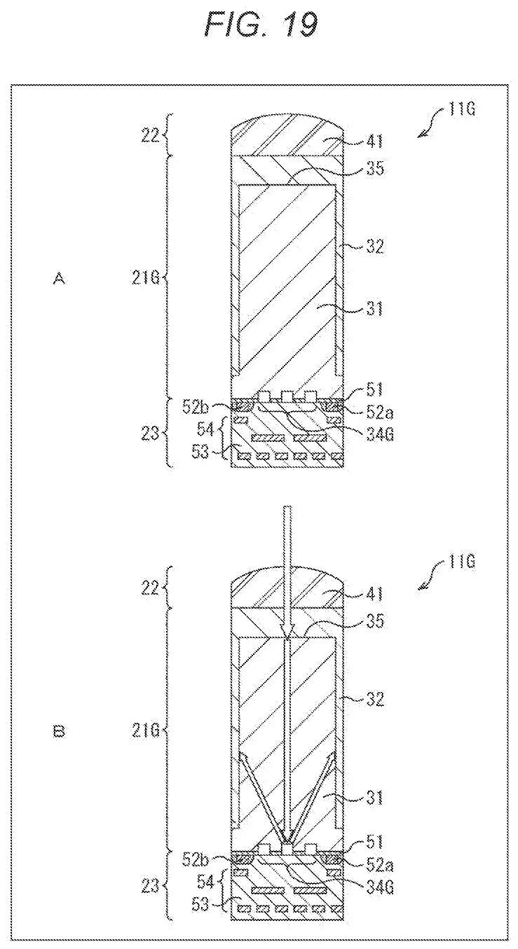

FIG. 19 is a diagram illustrating a first configuration example according to a second embodiment of a pixel that is provided in a sensor element to which the present technology has been applied. A of FIG. 19 illustrates a sectional configuration example of a pixel 11G, and B of FIG. 19 schematically illustrates a state where incident light that has entered the pixel 11G is diffracted or reflected. Note that, in regard to the configuration illustrated in FIG. 19 of the pixel 11G, the same reference signs are used in a configuration that is common to the configuration of the pixel 11 of FIG. 1, and the detailed description thereof is omitted.

As illustrated in FIG. 19, in the pixel 11G, similarly to the pixel 11 of FIG. 1, an on-chip lens layer 22 has been stacked on a light receiving surface side of a sensor substrate 21G, and a wiring layer 23 has been stacked on a circuit surface side of the sensor substrate 21G. Furthermore, in the pixel 11G, similarly to the transmission suppressing part 34 of the pixel 11 of FIG. 1, a transmission suppressing part 34G that includes an uneven structure including a plurality of shallow trenches has been formed on a circuit surface of a semiconductor layer 31.

On the other hand, the pixel 11G is different in a configuration from the pixel 11 of FIG. 1 in that a flat surface 35 has been formed on a light receiving surface of the semiconductor layer 31 in the sensor substrate 21G.

Stated another way, the pixel 11G has a structure in which the flat surface 35 is provided on the light receiving surface of the semiconductor layer 31 and the transmission suppressing part 34G is provided on the circuit surface of the semiconductor layer 31. The transmission suppressing part 34G includes an uneven structure that includes a plurality of shallow trenches.

Then, in the pixel 11G, as illustrated in B of FIG. 19, the transmission suppressing part 34G can suppress transmission through the semiconductor layer 31 to the outside of incident light that has advanced straight through the semiconductor layer 31 without diffraction on the flat surface 35. Here, in the pixel 11G, diffraction does not occur on the flat surface 35, and this can prevent, for example, a mixture of colors from occurring between adjacent pixels 11G.

Note that, in the pixel 11G, an antireflection film (not illustrated) that selectively prevents reflection of light in a predetermined wavelength range is formed on the flat surface 35. For example, an antireflection film that selectively prevents reflection of a near infrared wavelength ranging 700 nm to 1100 nm is used. Furthermore, for example, a ¼ wavelength type antireflection film that has a thickness of λ/4N (here, λ is a wavelength, and N is a refractive index of a medium) with respect to a center wavelength of a wavelength band of electromagnetic waves for which reflection is desired to be suppressed may be used. This ¼ wavelength type antireflection film has a refractive index that is greater than a refractive index of SiO2, and has a refractive index that is smaller than a refractive index of silicon.

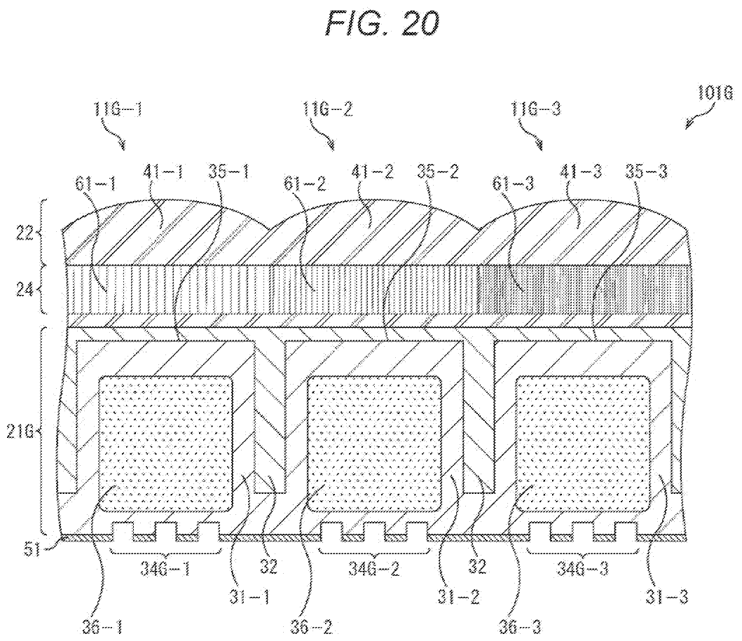

FIG. 20 illustrates sectional configurations of three pixels 11G-1 to 11G-3 in a solid-state imaging element 101G in which a plurality of pixels 11G has been arranged in an array shape, similarly to FIG. 3. Note that, in regard to the configuration illustrated in FIG. 20 of the solid-state imaging element 101G, the same reference signs are used in a configuration that is common to the configuration of the solid-state imaging element 101 of FIG. 3, and the detailed description thereof is omitted.

As illustrated in FIG. 20, in the solid-state imaging element 101G, transmission suppressing parts 34G-1 to 34G-3 are provided on circuit surfaces of respective semiconductor layers 31-1 to 31-3 in the pixels 11G-1 to 11G-3, and flat surfaces 35-1 to 35-3 are provided on light receiving surfaces.

In the solid-state imaging element 101G configured as described above, the pixels 11G-1 to 11G-3 can efficiently perform optical-to-electrical conversion on rays of light in respective wavelength ranges, and an image having a higher sensitivity can be captured.

Note that a planar layout of the pixels 11G in the solid-state imaging element 101G is similar to the planar layout described above and illustrated in FIG. 4 of the pixels 11 in the solid-state imaging element 101, and the illustration and description thereof are omitted.

<Second Configuration Example of Pixel According to Second Embodiment>

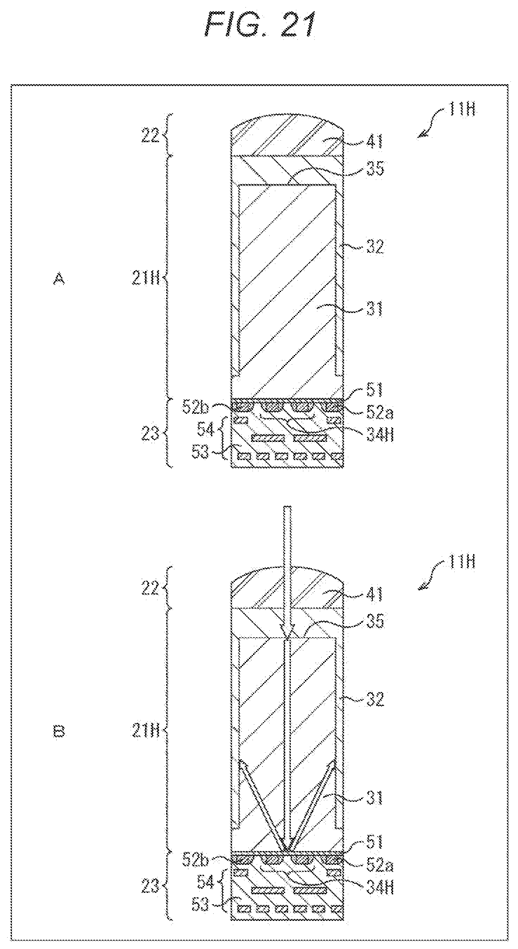

FIG. 21 is a diagram illustrating a second configuration example according to the second embodiment of a pixel that is provided in a sensor element to which the present technology has been applied. A of FIG. 21 illustrates a sectional configuration example of a pixel 11H, and B of FIG. 21 schematically illustrates a state where incident light that has entered the pixel 11H is diffracted or reflected. Note that, in regard to the configuration illustrated in FIG. 21 of the pixel 11H, the same reference signs are used in a configuration that is common to the configuration of the pixel 11 of FIG. 1, and the detailed description thereof is omitted.

As illustrated in FIG. 21, in the pixel 11H, similarly to the pixel 11 of FIG. 1, an on-chip lens layer 22 has been stacked on a light receiving surface side of a sensor substrate 21H, and a wiring layer 23 has been stacked on a circuit surface side of the sensor substrate 21H. Furthermore, in the pixel 11H, similarly to the transmission suppressing part 34C of the pixel 11C of FIG. 6, a transmission suppressing part 34H that includes an uneven structure including a plurality of dummy electrodes has been formed on a circuit surface of a semiconductor layer 31.

On the other hand, the pixel 11H is different in a configuration from the pixel 11 of FIG. 1 in that a flat surface 35 has been formed on a light receiving surface of the semiconductor layer 31 in the sensor substrate 21H.

Stated another way, the pixel 11H has a structure in which the flat surface 35 is provided on the light receiving surface of the semiconductor layer 31 and the transmission suppressing part 34H is provided on the circuit surface of the semiconductor layer 31. The transmission suppressing part 34H includes an uneven structure that includes a plurality of dummy electrodes.

Then, in the pixel 11H, as illustrated in B of FIG. 21, the transmission suppressing part 34H can suppress transmission through the semiconductor layer 31 to the outside of incident light that has advanced straight through the semiconductor layer 31 without diffraction on the flat surface 35. Here, in the pixel 11H, diffraction does not occur on the flat surface 35, and this can prevent, for example, a mixture of colors from occurring between adjacent pixels 11H.

Note that, in the pixel 11H, similarly to the description of the pixel 11G of FIG. 19, an antireflection film (not illustrated) that selectively prevents reflection of light in a predetermined wavelength range is formed on the flat surface 35.

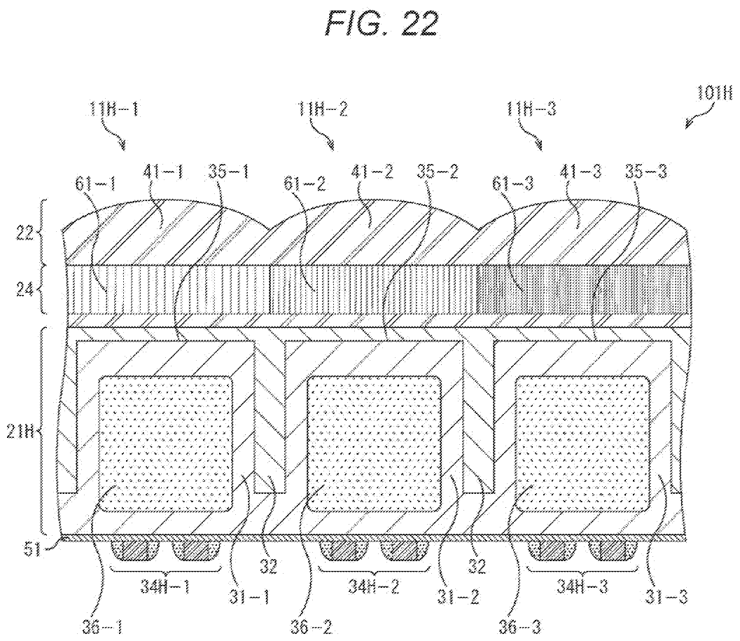

FIG. 22 illustrates sectional configurations of three pixels 11H-1 to 11H-3 in a solid-state imaging element 101H in which a plurality of pixels 11H has been arranged in an array shape, similarly to FIG. 3. Note that, in regard to the configuration illustrated in FIG. 22 of the solid-state imaging element 101H, the same reference signs are used in a configuration that is common to the configuration of the solid-state imaging element 101 of FIG. 3, and the detailed description thereof is omitted.

As illustrated in FIG. 22, in the solid-state imaging element 101H, transmission suppressing parts 34H-1 to 34H-3 are provided on circuit surfaces of respective semiconductor layers 31-1 to 31-3 in the pixels 11H-1 to 11H-3, and flat surfaces 35-1 to 35-3 are provided on light receiving surfaces.

In the solid-state imaging element 101H configured as described above, the pixels 11H-1 to 11H-3 can efficiently perform optical-to-electrical conversion on rays of light in respective wavelength ranges, and an image having a higher sensitivity can be captured.

Note that a planar layout of the pixels 11H in the solid-state imaging element 101H is similar to the planar layout described above and illustrated in FIG. 8 of the pixels 11C in the solid-state imaging element 101C, and the illustration and description thereof are omitted.

<Third Configuration Example of Pixel According to Second Embodiment>

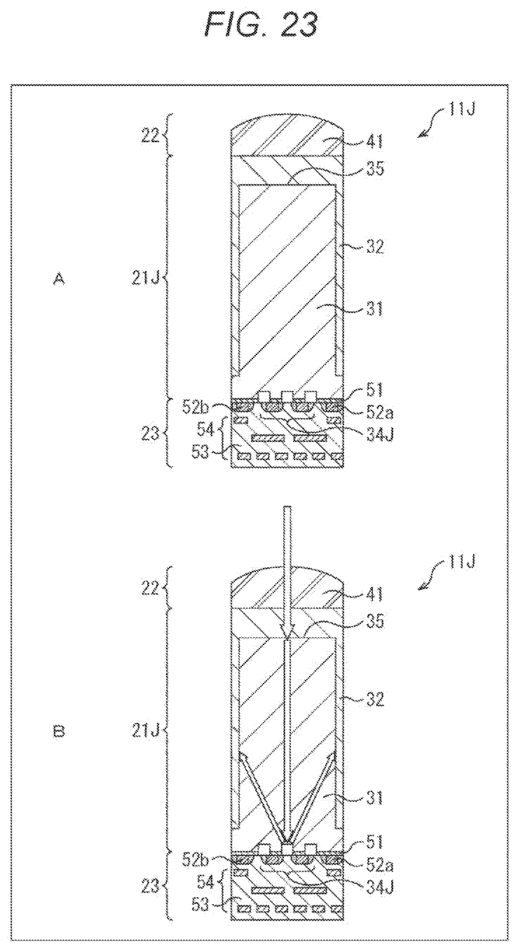

FIG. 23 is a diagram illustrating a third configuration example according to the second embodiment of a pixel that is provided in a sensor element to which the present technology has been applied. A of FIG. 23 illustrates a sectional configuration example of a pixel 11J, and B of FIG. 23 schematically illustrates a state where incident light that has entered the pixel 11J is diffracted or reflected. Note that, in regard to the configuration illustrated in FIG. 23 of the pixel 11J, the same reference signs are used in a configuration that is common to the configuration of the pixel 11 of FIG. 1, and the detailed description thereof is omitted.

As illustrated in FIG. 23, in the pixel 11J, similarly to the pixel 11 of FIG. 1, an on-chip lens layer 22 has been stacked on a light receiving surface side of a sensor substrate 21J, and a wiring layer 23 has been stacked on a circuit surface side of the sensor substrate 21J. Furthermore, in the pixel 11J, similarly to the transmission suppressing part 34D of the pixel 11D of FIG. 9, a transmission suppressing part 34J that includes an uneven structure that includes a plurality of shallow trenches and a plurality of dummy electrodes has been formed on a circuit surface of a semiconductor layer 31.

On the other hand, the pixel 11J is different in a configuration from the pixel 11 of FIG. 1 in that a flat surface 35 has been formed on a light receiving surface of the semiconductor layer 31 in the sensor substrate 21J.

Stated another way, the pixel 11J has a structure in which the flat surface 35 is provided on the light receiving surface of the semiconductor layer 31 and the transmission suppressing part 34J is provided on the circuit surface of the semiconductor layer 31. The transmission suppressing part 34J includes an uneven structure that includes a plurality of shallow trenches and a plurality of dummy electrodes.

Then, in the pixel 11J, as illustrated in B of FIG. 23, the transmission suppressing part 34J can suppress transmission through the semiconductor layer 31 to the outside of incident light that has advanced straight through the semiconductor layer 31 without diffraction on the flat surface 35. Here, in the pixel 11J, diffraction does not occur on the flat surface 35, and this can prevent, for example, a mixture of colors from occurring between adjacent pixels 11J.

Note that, in the pixel 11J, similarly to the description of the pixel 11G of FIG. 19, an antireflection film (not illustrated) that selectively prevents reflection of light in a predetermined wavelength range is formed on the flat surface 35.

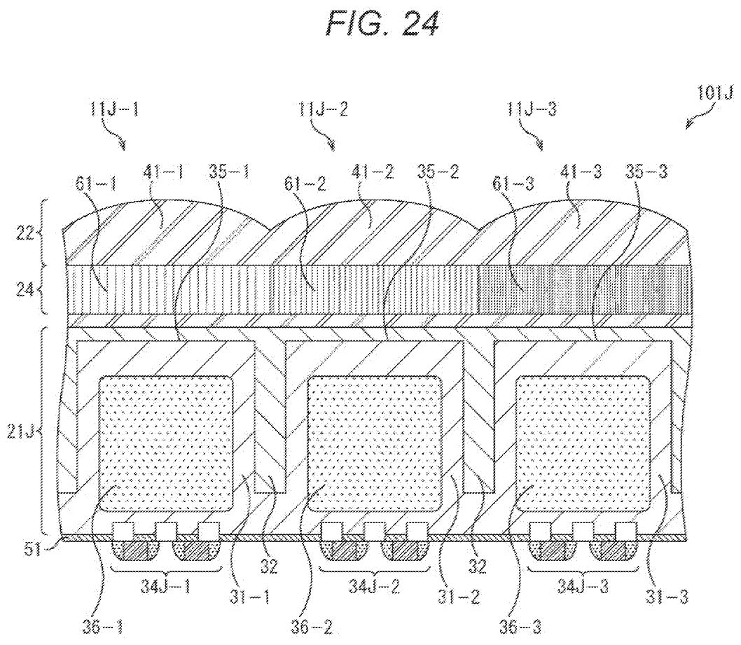

FIG. 24 illustrates sectional configurations of three pixels 11J-1 to 11J-3 in a solid-state imaging element 101J in which a plurality of pixels 11J has been arranged in an array shape, similarly to FIG. 3. Note that, in regard to the configuration illustrated in FIG. 24 of the solid-state imaging element 101J, the same reference signs are used in a configuration that is common to the configuration of the solid-state imaging element 101 of FIG. 3, and the detailed description thereof is omitted.

As illustrated in FIG. 24, in the solid-state imaging element 101J, transmission suppressing parts 34J-1 to 34J-3 are provided on circuit surfaces of respective semiconductor layers 31-1 to 31-3 in the pixels 11J-1 to 11J-3, and flat surfaces 35-1 to 35-3 are provided on light receiving surfaces.

In the solid-state imaging element 101J configured as described above, the pixels 11J-1 to 11J-3 can efficiently perform optical-to-electrical conversion on rays of light in respective wavelength ranges, and an image having a higher sensitivity can be captured.

Note that a planar layout of the pixels 11J in the solid-state imaging element 101J is similar to the planar layout described above and illustrated in FIG. 11 of the pixels 11D in the solid-state imaging element 101D, and the illustration and description thereof are omitted.

<Fourth Configuration Example of Pixel According to Second Embodiment>

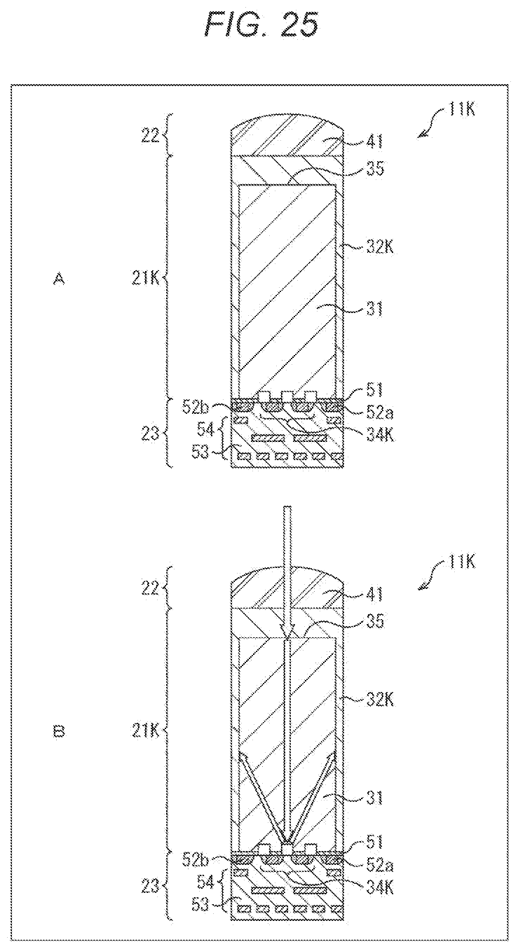

FIG. 25 is a diagram illustrating a fourth configuration example according to the second embodiment of a pixel that is provided in a sensor element to which the present technology has been applied. A of FIG. 25 illustrates a sectional configuration example of a pixel 11K, and B of FIG. 25 schematically illustrates a state where incident light that has entered the pixel 11K is diffracted or reflected. Note that, in regard to the configuration illustrated in FIG. 25 of the pixel 11K, the same reference signs are used in a configuration that is common to the configuration of the pixel 11 of FIG. 1, and the detailed description thereof is omitted.

As illustrated in FIG. 25, in the pixel 11K, similarly to the pixel 11 of FIG. 1, an on-chip lens layer 22 has been stacked on a light receiving surface side of a sensor substrate 21K, and a wiring layer 23 has been stacked on a circuit surface side of the sensor substrate 21K. Furthermore, in the pixel 11K, similarly to the transmission suppressing part 34E of the pixel 11E of FIG. 12, a transmission suppressing part 34K that includes an uneven structure that includes a plurality of shallow trenches and a plurality of dummy electrodes has been formed on a circuit surface of a semiconductor layer 31.

On the other hand, the pixel 11K is different in a configuration from the pixel 11 of FIG. 1 in that a flat surface 35 has been formed on a light receiving surface of the semiconductor layer 31 in the sensor substrate 21K. Moreover, in the pixel 11K, similarly to the DTI 32E of the pixel 11E of FIG. 12, a DTI 32K has a penetrating structure that causes semiconductor layers 31 of adjacent pixels 11K to be completely isolated from each other.

Stated another way, the pixel 11K has a structure in which the flat surface 35 is provided on the light receiving surface of the semiconductor layer 31 and the transmission suppressing part 34K is provided on the circuit surface of the semiconductor layer 31. The transmission suppressing part 34K includes an uneven structure that includes a plurality of shallow trenches and a plurality of dummy electrodes. Moreover, in the pixel 11K, the DTI 32K has a penetrating structure.

Then, in the pixel 11K, as illustrated in B of FIG. 25, the transmission suppressing part 34K can suppress transmission through the semiconductor layer 31 to the outside of incident light that has advanced straight through the semiconductor layer 31 without diffraction on the flat surface 35. Here, in the pixel 11K, diffraction does not occur on the flat surface 35, and this can prevent, for example, a mixture of colors from occurring between adjacent pixels 11K.

Note that, in the pixel 11K, similarly to the description of the pixel 11G of FIG. 19, an antireflection film (not illustrated) that selectively prevents reflection of light in a predetermined wavelength range is formed on the flat surface 35.

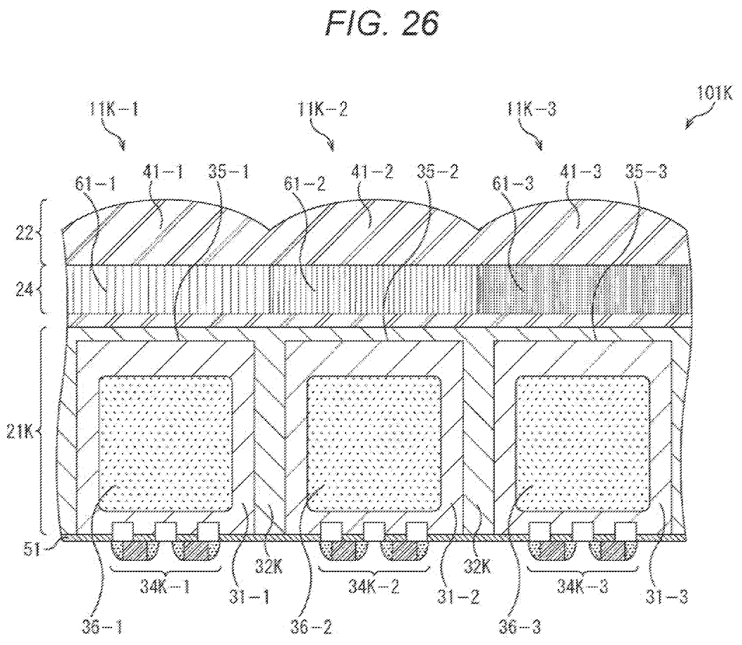

FIG. 26 illustrates sectional configurations of three pixels 11K-1 to 11K-3 in a solid-state imaging element 101K in which a plurality of pixels 11K has been arranged in an array shape, similarly to FIG. 3. Note that, in regard to the configuration illustrated in FIG. 26 of the solid-state imaging element 101K, the same reference signs are used in a configuration that is common to the configuration of the solid-state imaging element 101 of FIG. 3, and the detailed description thereof is omitted.

As illustrated in FIG. 26, in the solid-state imaging element 101K, transmission suppressing parts 34K-1 to 34K-3 are provided on circuit surfaces of respective semiconductor layers 31-1 to 31-3 in the pixels 11K-1 to 11K-3, and flat surfaces 35-1 to 35-3 are provided on light receiving surfaces. Then, the DTIs 32K having a penetrating structure completely isolate the pixels 11K-1 to 11K-3 from each other.

In the solid-state imaging element 101K configured as described above, the pixels 11K-1 to 11K-3 can efficiently perform optical-to-electrical conversion on rays of light in respective wavelength ranges, and an image having a higher sensitivity can be captured.

Note that a planar layout of the pixels 11K in the solid-state imaging element 101K is similar to the planar layout described above and illustrated in FIG. 11 of the pixels 11D in the solid-state imaging element 101D, and the illustration and description thereof are omitted.

<Fifth Configuration Example of Pixel According to Second Embodiment>

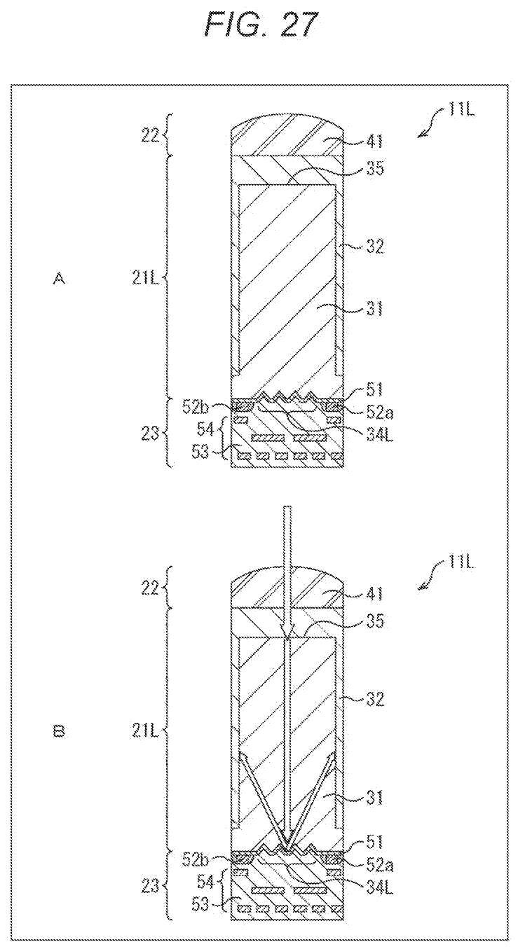

FIG. 27 is a diagram illustrating a fifth configuration example according to the second embodiment of a pixel that is provided in a sensor element to which the present technology has been applied. A of FIG. 27 illustrates a sectional configuration example of a pixel 11L, and B of FIG. 27 schematically illustrates a state where incident light that has entered the pixel 11L is diffracted or reflected. Note that, in regard to the configuration illustrated in FIG. 27 of the pixel 11L, the same reference signs are used in a configuration that is common to the configuration of the pixel 11 of FIG. 1, and the detailed description thereof is omitted.

As illustrated in FIG. 27, in the pixel 11L, similarly to the pixel 11 of FIG. 1, an on-chip lens layer 22 has been stacked on a light receiving surface side of a sensor substrate 21L, and a wiring layer 23 has been stacked on a circuit surface side of the sensor substrate 21L. Furthermore, in the pixel 11L, similarly to the transmission suppressing part 34F of the pixel 11F of FIG. 14, a transmission suppressing part 34L that includes an uneven structure formed by providing a plurality of quadrangular pyramid shapes or reversed quadrangular pyramid shapes at predetermined intervals has been formed on a circuit surface of a semiconductor layer 31.

Here, in the transmission suppressing part 34L, the uneven structure is formed, for example, in such a way that a plane index of a crystal surface of a single crystal silicon wafer is 110. Note that, for example, an uneven structure that is formed by using a plane index of 110 is shallower than an uneven structure that is formed by using a plane index of 111, and is relatively offset by 45° with respect to the uneven structure that is formed by using a plane index of 111 (see FIG. 15).

On the other hand, the pixel 11L is different in a configuration from the pixel 11 of FIG. 1 in that a flat surface 35 has been formed on a light receiving surface of the semiconductor layer 31 in the sensor substrate 21L.

Stated another way, the pixel 11L has a structure in which the flat surface 35 is provided on the light receiving surface of the semiconductor layer 31 and the transmission suppressing part 34L is provided on the circuit surface of the semiconductor layer 31. The transmission suppressing part 34L includes an uneven structure formed by providing a plurality of quadrangular pyramid shapes or reversed quadrangular pyramid shapes at predetermined intervals in such a way that a plane index is 110.

Then, in the pixel 11L, as illustrated in B of FIG. 27, the transmission suppressing part 34L can suppress transmission through the semiconductor layer 31 to the outside of incident light that has advanced straight through the semiconductor layer 31 without diffraction on the flat surface 35. Here, in the pixel 11L, diffraction does not occur on the flat surface 35, and this can prevent, for example, a mixture of colors from occurring between adjacent pixels 11L.

Note that, in the pixel 11L, similarly to the description of the pixel 11G of FIG. 19, an antireflection film (not illustrated) that selectively prevents reflection of light in a predetermined wavelength range is formed on the flat surface 35.

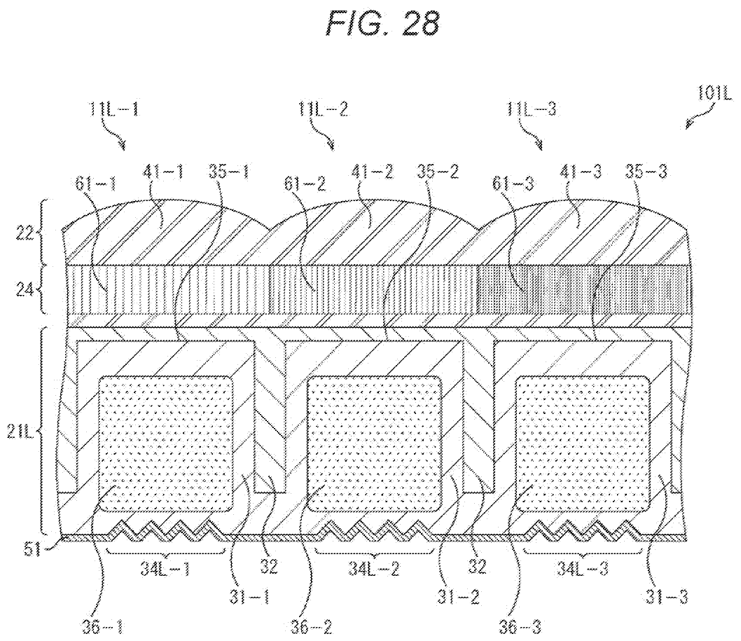

FIG. 28 illustrates sectional configurations of three pixels 11L-1 to 11L-3 in a solid-state imaging element 101L in which a plurality of pixels 11L has been arranged in an array shape, similarly to FIG. 3. Note that, in regard to the configuration illustrated in FIG. 28 of the solid-state imaging element 101L, the same reference signs are used in a configuration that is common to the configuration of the solid-state imaging element 101 of FIG. 3, and the detailed description thereof is omitted.

As illustrated in FIG. 28, in the solid-state imaging element 101L, transmission suppressing parts 34L-1 to 34L-3 are provided on circuit surfaces of respective semiconductor layers 31-1 to 31-3 in the pixels 11L-1 to 11L-3, and flat surfaces 35-1 to 35-3 are provided on light receiving surfaces.

In the solid-state imaging element 101L configured as described above, the pixels 11L-1 to 11L-3 can efficiently perform optical-to-electrical conversion on rays of light in respective wavelength ranges, and an image having a higher sensitivity can be captured.

Note that a planar layout of the pixels 11L in the solid-state imaging element 101L is similar to a planar layout obtained by removing the reflection suppressing parts 33-1 to 33-9 from the planar layout described above and illustrated in FIG. 18 of the pixels 11F in the solid-state imaging element 101F, and the illustration and description thereof are omitted.

<Sixth Configuration Example of Pixel According to Second Embodiment>

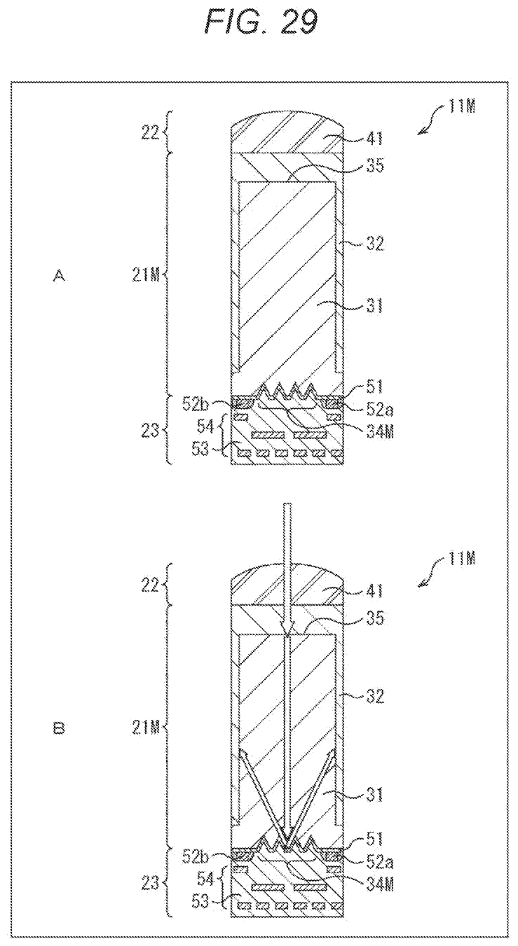

FIG. 29 is a diagram illustrating a sixth configuration example according to the second embodiment of a pixel that is provided in a sensor element to which the present technology has been applied. A of FIG. 29 illustrates a sectional configuration example of a pixel 11M, and B of FIG. 29 schematically illustrates a state where incident light that has entered the pixel 11M is diffracted or reflected. Note that, in regard to the configuration illustrated in FIG. 29 of the pixel 11M, the same reference signs are used in a configuration that is common to the configuration of the pixel 11 of FIG. 1, and the detailed description thereof is omitted.

As illustrated in FIG. 29, in the pixel 11M, similarly to the pixel 11 of FIG. 1, an on-chip lens layer 22 has been stacked on a light receiving surface side of a sensor substrate 21M, and a wiring layer 23 has been stacked on a circuit surface side of the sensor substrate 21M. Furthermore, in the pixel 11M, similarly to the transmission suppressing part 34F of the pixel 11F of FIG. 14, a transmission suppressing part 34M that includes an uneven structure formed by providing a plurality of quadrangular pyramid shapes or reversed quadrangular pyramid shapes at predetermined intervals has been formed on a circuit surface of a semiconductor layer 31.

Here, in the transmission suppressing part 34M, the uneven structure is formed, for example, in such a way that a plane index of a crystal surface of a single crystal silicon wafer is 111. Note that, for example, an uneven structure that is formed by using a plane index of 111 is deeper than an uneven structure that is formed by using a plane index of 110, and is relatively offset by 45° with respect to the uneven structure that is formed by using a plane index of 110 (see FIG. 15).

On the other hand, the pixel 11M is different in a configuration from the pixel 11 of FIG. 1 in that a flat surface 35 has been formed on a light receiving surface of the semiconductor layer 31 in the sensor substrate 21M.

Stated another way, the pixel 11M has a structure in which the flat surface 35 is provided on the light receiving surface of the semiconductor layer 31 and the transmission suppressing part 34M is provided on the circuit surface of the semiconductor layer 31. The transmission suppressing part 34M includes an uneven structure formed by providing a plurality of quadrangular pyramid shapes or reversed quadrangular pyramid shapes at predetermined intervals in such a way that a plane index is 111.

Then, in the pixel 11M, as illustrated in B of FIG. 29, the transmission suppressing part 34M can suppress transmission through the semiconductor layer 31 to the outside of incident light that has advanced straight through the semiconductor layer 31 without diffraction on the flat surface 35. Here, in the pixel 11M, diffraction does not occur on the flat surface 35, and this can prevent, for example, a mixture of colors from occurring between adjacent pixels 11M.

Note that, in the pixel 11M, similarly to the description of the pixel 11G of FIG. 19, an antireflection film (not illustrated) that selectively prevents reflection of light in a predetermined wavelength range is formed on the flat surface 35.

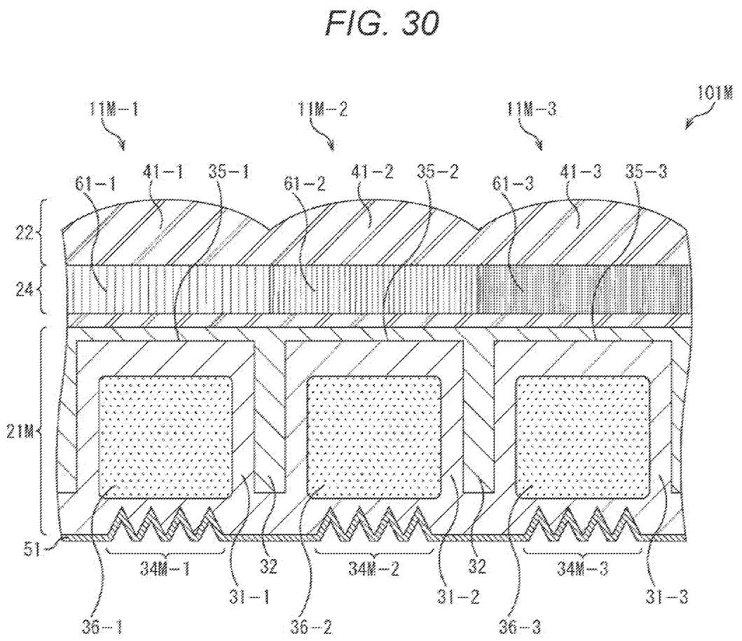

FIG. 30 illustrates sectional configurations of three pixels 11M-1 to 11M-3 in a solid-state imaging element 101M in which a plurality of pixels 11M has been arranged in an array shape, similarly to FIG. 3. Note that, in regard to the configuration illustrated in FIG. 30 of the solid-state imaging element 101M, the same reference signs are used in a configuration that is common to the configuration of the solid-state imaging element 101 of FIG. 3, and the detailed description thereof is omitted.

As illustrated in FIG. 30, in the solid-state imaging element 101M, transmission suppressing parts 34M-1 to 34M-3 are provided on circuit surfaces of respective semiconductor layers 31-1 to 31-3 in the pixels 11M-1 to 11M-3, and flat surfaces 35-1 to 35-3 are provided on light receiving surfaces.

In the solid-state imaging element 101M configured as described above, the pixels 11M-1 to 11M-3 can efficiently perform optical-to-electrical conversion on rays of light in respective wavelength ranges, and an image having a higher sensitivity can be captured.

Note that a planar layout of the pixels 11M in the solid-state imaging element 101M is similar to a planar layout obtained by removing the reflection suppressing parts 33-1 to 33-9 from the planar layout described above and illustrated in FIG. 18 of the pixels 11F in the solid-state imaging element 101F, and the illustration and description thereof are omitted.

<Sensor Potential and Vertical Transistor>

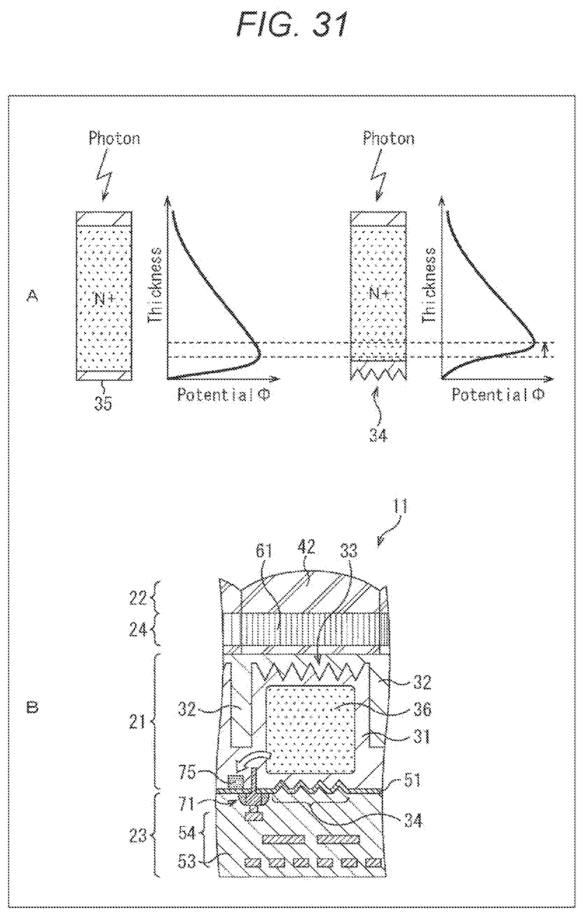

A sensor potential and a vertical transistor are described with reference to FIG. 31.

A of FIG. 31 illustrates an example of potentials in a configuration in which the flat surface 35 has been formed on the circuit surface of the semiconductor layer 31 and in a configuration in which the transmission suppressing part 34 has been formed on the circuit surface of the semiconductor layer 31. As illustrated, in a configuration in which the transmission suppressing part 34 is provided on the circuit surface of the semiconductor layer 31, a range of a deep potential is located on an inner side of the semiconductor layer 31 (in a position far from the circuit surface) in comparison with a configuration in which the circuit surface of the semiconductor layer 31 is the flat surface 35.

Accordingly, as illustrated in B of FIG. 31, in a pixel 11, it is preferable that a transfer transistor 71 having a vertical structure in which part of an electrode is embedded up to a predetermined depth from a circuit surface of a semiconductor layer 31 be used in order to transfer an electric charge from an optical-to-electrical converter 36 to an FD unit 75. As described above, by using the transfer transistor 71 having a vertical structure, an electric charge can be satisfactorily transferred from the optical-to-electrical converter 36 to the FD unit 75 even in a configuration in which a potential becomes deep in a position away from the circuit surface by providing the transmission suppressing part 34, as in the pixel 11.

Furthermore, a configuration may be employed in which high-concentration P-type impurities are implanted into a region around the transmission suppressing part 34 including a region where the transmission suppressing part 34 is provided, on the circuit surface of the semiconductor layer 31 on which the transmission suppressing part 34 is provided, or the region around the transmission suppressing part 34 including the region where the transmission suppressing part 34 is provided is electrically pinned by a film having a negative fixed charge. This enables a gradient of a potential to become steeper.

<Pitch Size of Diffractive Structure>

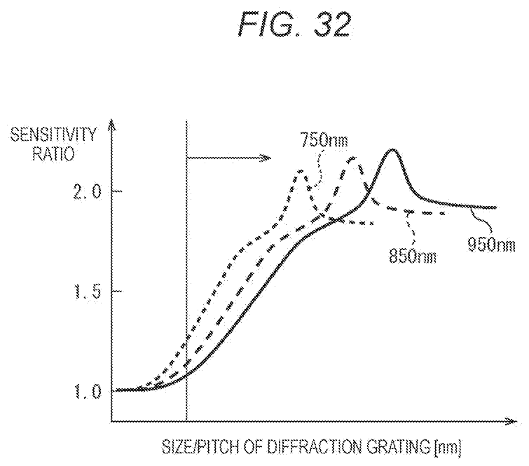

A pitch size of a diffractive structure is described with reference to FIG. 32.

In FIG. 32, a vertical axis indicates a sensitivity of a pixel 11, and the sensitivity of the pixel 11 is indicated as a sensitivity ratio to the pixel 11A having a conventional structure, as illustrated in A of FIG. 2. Furthermore, a horizontal axis indicates a pitch size of a diffractive structure formed in the transmission suppressing part 34 (that is, an uneven structure of the transmission suppressing part 34 according to each of the embodiments described above and in each of the configuration examples described above). Then, FIG. 32 illustrates a result of simulating a sensitivity with respect to a size of a pitch of the uneven structure for each wavelength (750 nm, 850 nm, or 950 nm) of incident light that enters the pixel 11.

It is indicated, for example, that, as the pitch size of the diffractive structure formed in the transmission suppressing part 34 increases, the sensitivity of the pixel 11 increases, and light is trapped more effectively. Then, a pitch size that causes a maximum sensitivity changes according to the wavelength of incident light, and it is preferable that the pitch size of the diffractive structure be appropriately selected according to a wavelength serving as a target for optical-to-electrical conversion in the pixel 11.

Note that it is known that an efficiency of diffraction using a light diffractive structure has a relationship with a physical size of the structure and a wavelength, and specifically, in a structure in a SiO2 medium, a small effect is exhibited when a pitch size is less than or equal to about 200 nm, and a degree of improvements also decreases when the pitch size is greater than 1000 nm.

<Application to Electronic Device>

The solid-state imaging element 101 described above can be applied to an electronic device such as what is called a smartphone or a tablet, for example.

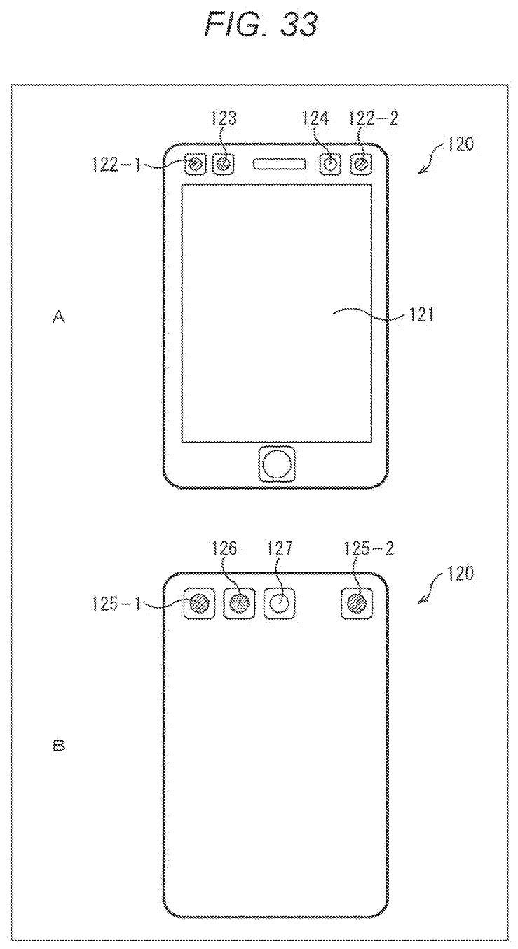

FIG. 33 is a diagram illustrating an example of the external appearance of an electronic device 120 on which the solid-state imaging element 101 is mounted. A of FIG. 33 illustrates a side of a front surface of the electronic device 120, and B of FIG. 33 illustrates a side of a back surface of the electronic device 120.

As illustrated in A of FIG. 33, a display 121 that displays an image is disposed at a center of the front surface of the electronic device 120. Then, front cameras 122-1 and 122-2 that use the solid-state imaging element 101, an IR light source 123 that emits infrared light, and a visible light source 124 that emits visible light are disposed along an upper side of the front surface of the electronic device 120.

Furthermore, as illustrated in B of FIG. 33, rear cameras 125-1 and 125-2 that use the solid-state imaging element 101, an IR light source 126 that emits infrared light, and a visible light source 127 that emits visible light are disposed along an upper side of the back surface of the electronic device 120.

By applying the solid-state imaging element 101 described above to the electronic device 120 configured as described above, for example, an image having a higher sensitivity can be captured. Note that the solid-state imaging element 101 can be applied to another electronic device such as an infrared sensor, a ranging sensor that uses an active infrared light source, a security camera, or a personal or biometric authentication camera. This enables improvements in sensitivity, performance, or the like of these electronic devices. Furthermore, a reduction in power consumption of a system can be achieved due to a reduction in power of a light source.

<Circuit Configuration Example of Solid-State Imaging Element>

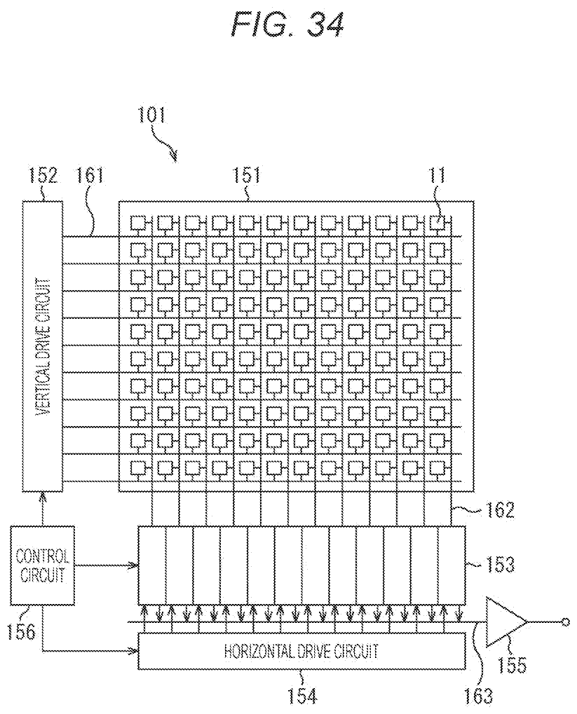

An example of a circuit configuration of a solid-state imaging element is described with reference to FIG. 34.

As illustrated in FIG. 34, the solid-state imaging element 101 includes a pixel region 151, a vertical drive circuit 152, a column signal processing circuit 153, a horizontal drive circuit 154, an output circuit 155, and a control circuit 156.

The pixel region 151 is a light receiving surface that receives light that has been condensed by a not-illustrated optical system. In the pixel region 151, a plurality of pixels 11 is arranged in a matrix shape. Each of the rows of respective pixels 11 is connected to the vertical drive circuit 152 via a horizontal signal line 161, and each of the columns of the respective pixels 11 is connected to the column signal processing circuit 153 via a vertical signal line 162. Each of the plurality of pixels 11 outputs a pixel signal having a level that corresponds to an amount of received light, and an image of a subject to be formed in the pixel region 151 is constructed from the pixel signals.

The vertical drive circuit 152 sequentially supplies a drive signal for driving (transfer, selection, resetting, or the like) of each of the plurality of pixels 11 via the horizontal signal line 161 to each of the rows of the pixels 11 that are arranged in the pixel region 151. The column signal processing circuit 153 performs correlated double sampling (CDS) processing on pixel signals that have been output from the plurality of pixels 11 via the vertical signal line 162 to perform AD conversion on the pixel signals and to remove reset noise.

The horizontal drive circuit 154 sequentially supplies the column signal processing circuit 153 with a drive signal for causing a pixel signal to be output from the column signal processing circuit 153 to a data output signal line 163 for each of the columns of the plurality of pixels 11 that are arranged in the pixel region 151. The output circuit 155 amplifies pixel signals that have been supplied from the column signal processing circuit 153 via the data output signal line 163 at a timing according to the drive signal of the horizontal drive circuit 154, and outputs the pixel signals to a rear-stage signal processing circuit. The control circuit 156 controls the drive of each block of the solid-state imaging element 101, for example, by generating and supplying a clock signal according to a drive cycle of each of the blocks.

The solid-state imaging element 101 is configured as described above, the pixel 11 according to each of the embodiments described above and in each of the configuration examples described above can be applied to the solid-state imaging element 101, and for example, an image having a higher sensitivity can be captured.

<Configuration Example of Electronic Device>

A solid-state imaging element 101, as described above, can be applied to various electronic devices, e.g., an imaging system such as a digital still camera or a digital video camera, a mobile phone having an imaging function, or another device having the imaging function.

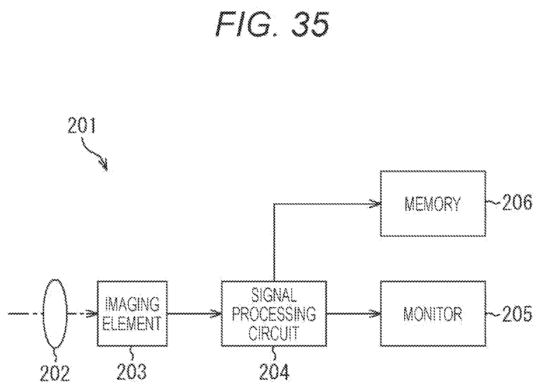

FIG. 35 is a block diagram illustrating a configuration example of an imaging apparatus that is mounted on an electronic device.

As illustrated in FIG. 35, an imaging apparatus 201 includes an optical system 202, an imaging element 203, a signal processing circuit 204, a monitor 205, and a memory 206, and can capture a still image and a moving image.

The optical system 202 includes one or a plurality of lenses, guides, to the imaging element 203, image light (incident light) from a subject, and causes an image to be formed on a light receiving surface (a sensor unit) of the imaging element 203.

As the imaging element 203, the solid-state imaging element 101 described above is applied. In the imaging element 203, electrons are accumulated, during a prescribed period, to correspond to the image formed on the light receiving surface via the optical system 202. Then, a signal that corresponds to the electrons accumulated in the imaging element 203 is supplied to the signal processing circuit 204.

The signal processing circuit 204 performs various types of signal processing on a pixel signal that has been output from the imaging element 203. An image (image data) that has been obtained by the signal processing circuit 204 performing signal processing is supplied to the monitor 205 and is displayed on the monitor 205, or is supplied to the memory 206 and is stored (recorded) in the memory 206.

By applying the solid-state imaging element 101 described above to the imaging apparatus 201 configured as described above, for example, an image having a higher sensitivity can be captured.

<Usage Examples of Image Sensor>

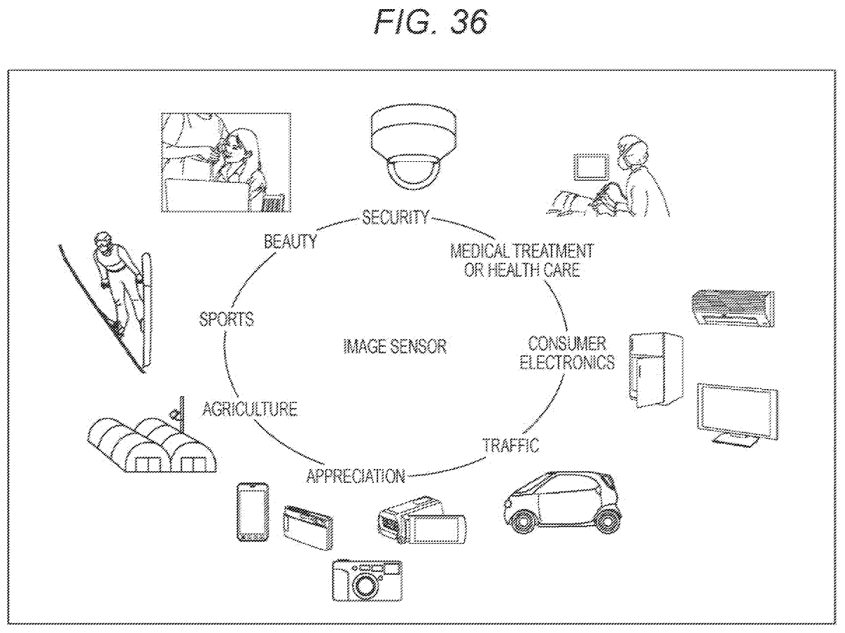

FIG. 36 is a diagram illustrating usage examples in which the image sensor (the imaging element) described above is used.

The image sensor described above can be used, for example, in various cases where light, such as visible light, infrared light, ultraviolet light, or X-rays, is sensed, as described below.
Devices provided for appreciation that capture images, such as digital cameras or portable devices having a camera function
Devices provided for traffic, such as on-vehicle sensors that image a front side, a rear side, the periphery, an inside, or the like of an automobile for the purpose of safe driving such as automatic stop, the recognition of the state of a driver, or the like, monitoring cameras that monitor travelling vehicles or roads, or ranging sensors that measure a distance between vehicles or the like
Devices provided as consumer electronics, such as TVs, refrigerators, or air conditioners, for the purpose of imaging a user's gesture and operating a device in accordance with the gesture
Devices provided for medical treatment or health care, such as endoscopes or devices that perform angiography by receiving infrared light
Devices provided for security, such as monitoring cameras for crime prevention or cameras for personal authentication
Devices provided for beauty, such as skin measuring devices that image skin or microscopes that image a scalp
Devices provided for sports, such as action cameras or wearable cameras for sport usage or the like
Devices provided for agriculture, such as cameras that monitor the state of fields or crops

<Example of Utilization in Moving Body>

The technology according to the present disclosure (the present technology) can be utilized in a variety of products. For example, the technology according to the present disclosure may be implemented as an apparatus that is mounted in any type of moving body of an automobile, an electric automobile, a hybrid electric automobile, a motorcycle, a bicycle, a personal mobility, an airplane, a drone, a ship, a robot, or the like.

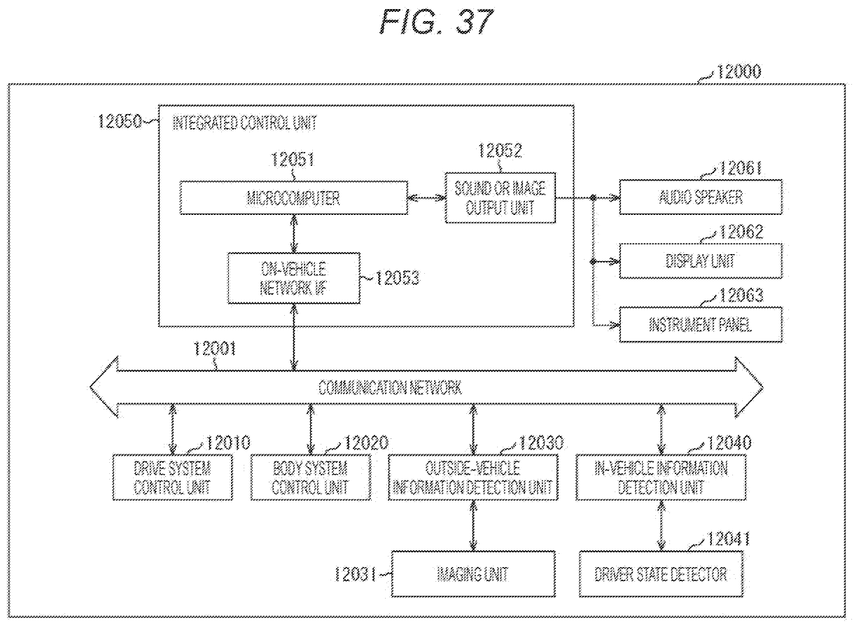

FIG. 37 is a block diagram illustrating a schematic configuration example of a vehicle control system that is an example of a moving body control system to which the technology according to the present disclosure can be applied.

A vehicle control system 12000 includes a plurality of electronic control units that is connected via a communication network 12001. In the example illustrated in FIG. 37, the vehicle control system 12000 includes a drive system control unit 12010, a body system control unit 12020, an outside-vehicle information detection unit 12030, an in-vehicle information detection unit 12040, and an integrated control unit 12050. Furthermore, as a functional configuration of the integrated control unit 12050, a microcomputer 12051, a sound or image output unit 12052, and an on-vehicle network interface (I/F) 12053 are illustrated.

The drive system control unit 12010 controls an operation of a device that relates to a drive system of a vehicle in accordance with various programs. For example, the drive system control unit 12010 functions as a control device of a drive force generation device that generates a drive force of a vehicle, such as an internal combustion engine or a drive motor, a drive force transmission mechanism that transmits the drive force to wheels, a steering mechanism that adjusts a steering angle of the vehicle, a braking device that generates a braking force of the vehicle, and the like.

The body system control unit 12020 controls operations of various devices equipped in a vehicle body in accordance with various programs. For example, the body system control unit 12020 functions as a control device of a keyless entry system, a smart key system, a power window device, or various lamps such as a headlamp, a back lamp, a brake lamp, a turn signal, or a fog lamp. In this case, radio waves transmitted from a portable machine that is substituted for a key or signals of various switches can be input to the body system control unit 12020. The body system control unit 12020 receives an input of these radio waves or signals, and controls a door locking device, the power window device, a lamp, or the like of the vehicle.

The outside-vehicle information detection unit 12030 detects information relating to the outside of a vehicle in which the vehicle control system 12000 is mounted. For example, the outside-vehicle information detection unit 12030 is connected to an imaging unit 12031. The outside-vehicle information detection unit 12030 causes the imaging unit 12031 to capture an image of the outside of the vehicle, and receives the captured image. The outside-vehicle information detection unit 12030 may perform object detection processing or distance detection processing on a person, a car, an obstacle, a traffic sign, characters on a road surface, or the like on the basis of the received image.

The imaging unit 12031 is an optical sensor that receives light and outputs an electric signal that corresponds to an amount of the received light. The imaging unit 12031 can output the electric signal as an image, or can output the electric signal as information of ranging. Furthermore, light received by the imaging unit 12031 may be visible light, or may be invisible light such as infrared rays.

The in-vehicle information detection unit 12040 detects information relating to the inside of the vehicle. The in-vehicle information detection unit 12040 is connected, for example, to a driver state detector 12041 that detects a state of a driver. The driver state detector 12041 includes, for example, a camera that images a driver, and the in-vehicle information detection unit 12040 may calculate a fatigue degree or a concentration degree of the driver or may determine whether or not the driver is dozing on the basis of detection information input from the driver state detector 12041.

The microcomputer 12051 can calculate a control target value of the drive force generation device, the steering mechanism, or the braking device on the basis of in-vehicle or outside-vehicle information acquired by the outside-vehicle information detection unit 12030 or the in-vehicle information detection unit 12040, and can output a control command to the drive system control unit 12010. For example, the microcomputer 12051 can perform cooperative control aiming at implementing a function of an advanced driver assistance system (ADAS) including vehicle collision avoidance or impact mitigation, follow-up traveling based on a distance between vehicles, vehicle speed maintaining traveling, vehicle collision warning, vehicle lane departure warning, or the like.

Furthermore, the microcomputer 12051 can perform cooperative control aiming at automatic driving or the like for autonomously traveling independently of a driver's operation, by controlling the drive force generation device, the steering mechanism, the braking device, or the like on the basis of information relating to the periphery of the vehicle that has been acquired by the outside-vehicle information detection unit 12030 or the in-vehicle information detection unit 12040.

Furthermore, the microcomputer 12051 can output a control command to the body system control unit 12030 on the basis of outside-vehicle information acquired by the outside-vehicle information detection unit 12030. For example, the microcomputer 12051 can perform cooperative control aiming at antiglare, such as controlling a headlamp in accordance with a position of a preceding vehicle or an oncoming vehicle that has been sensed by the outside-vehicle information detection unit 12030 to switch a high beam to a low beam.

The sound or image output unit 12052 transmits an output signal of at least one of sound or an image to an output device that can visually or aurally report information to a passenger of a vehicle or the outside of the vehicle. In the example of FIG. 37, an audio speaker 12061, a display unit 12062, and an instrument panel 12063 are illustrated as the output device. The display unit 12062 may include, for example, at least one of an on-board display or a head-up display.

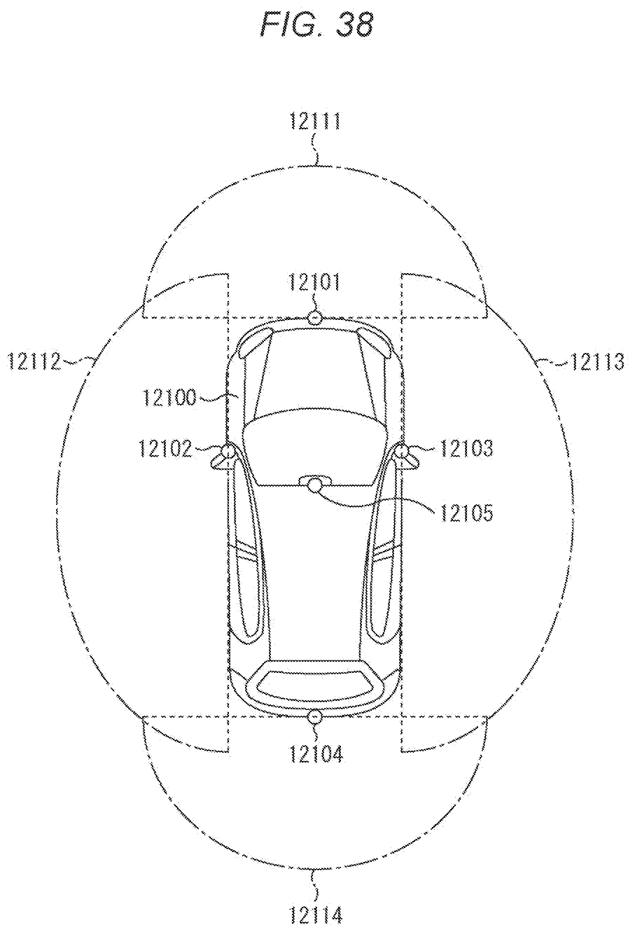

FIG. 38 is a diagram illustrating an example of an installation position of the imaging unit 12031.

FIG. 38 illustrates imaging units 12101, 12102, 12103, 12104, and 12105 as the imaging unit 12031.

The imaging units 12101, 12102, 12103, 12104, and 12105 are provided in positions, for example, a front nose, a side-view mirror, a rear bumper, a back door, an upper portion of a windshield in a vehicle cabin, and the like, of a vehicle 12100. The imaging unit 12101 included in the front nose and the imaging unit 12105 included in the upper portion of the windshield in the vehicle cabin principally acquire an image of a front side of the vehicle 12100. The imaging units 12102 and 12103 included in the side-view mirrors principally acquire images of sides of the vehicle 12100. The imaging unit 12104 included in the rear bumper or the back door principally acquires an image of a rear side of the vehicle 12100. The imaging unit 12105 included in the upper portion of the windshield in the vehicle cabin is principally used to detect a preceding vehicle, or a pedestrian, an obstacle, a traffic light, a traffic sign, a traffic lane, or the like.

Note that FIG. 38 illustrates examples of imaging ranges of the imaging units 12101 to 12104. An imaging range 12111 indicates an imaging range of the imaging unit 12101 provided in the front nose, imaging ranges 12112 and 12113 respectively indicate imaging ranges of the imaging units 12102 and 12103 provided in the side-view mirrors, and an imaging range 12114 indicates an imaging range of the imaging unit 12104 provided in the rear bumper or the back door. For example, an overhead image in which the vehicle 12100 is viewed from the above is obtained by superimposing pieces of image data that have been captured by the imaging units 12101 to 12104 onto each other.

At least one of the imaging units 12101 to 12104 may have a function of acquiring distance information. For example, at least one of the imaging units 12101 to 12104 may be a stereo camera including a plurality of imaging elements, or may be an imaging element including pixels for the detection of a phase difference.

For example, the microcomputer 12051 can extract, in particular, a three-dimensional object that is located closest on an advancing route of the vehicle 12100 and travels at a predetermined speed (for example, 0 km/h or more) in almost the same direction as a direction of the vehicle 12100 to be a preceding vehicle, by obtaining a distance to each three-dimensional object in the imaging ranges 12111 to 12114 and a temporal change in this distance (a relative speed with respect to the vehicle 12100) on the basis of distance information acquired from the imaging units 12101 to 12104. Moreover, the microcomputer 12051 can set, in advance, a distance between vehicles to be secured in front of a preceding vehicle, and can perform automatic braking control (including follow-up stop control), automatic acceleration control (including follow-up starting control), and the like. As described above, cooperative control can be performed that aims at automatic driving or the like for autonomously traveling independently of a driver's operation.

For example, the microcomputer 12051 can classify pieces of three-dimensional data relating to three-dimensional objects into a motorcycle, an ordinary vehicle, a large vehicle, a pedestrian, and another three-dimensional object such as a telegraph pole on the basis of the distance information acquired from the imaging units 12101 to 12104 to extract the pieces of three-dimensional data, and can use the pieces of three-dimensional data to automatically avoid an obstacle. For example, the microcomputer 12051 identifies obstacles around the vehicle 12100 to divide the obstacles into obstacles that a driver of the vehicle 12100 can visually recognize and obstacles that are difficult to visually recognize. Then, the microcomputer 12051 determines a collision risk indicating a risk degree of collision against each of the obstacles. In a situation where the collision risk is greater than or equal to a setting value and there is a possibility of collision, the microcomputer 12051 can perform driving assistance for collision avoidance, by outputting an alarm to the driver via the audio speaker 12061 or the display unit 12062, or performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not the pedestrian is present in images captured by the imaging units 12101 to 12104. Such recognition of a pedestrian is performed, for example, in a procedure of extracting feature points in images captured by the imaging units 12101 to 12104 serving as infrared cameras and a procedure of performing pattern matching processing on consecutive feature points indicating the contour of an object and determining whether or not the consecutive feature points indicate a pedestrian. When the microcomputer 12051 determines that a pedestrian is present in the images captured by the imaging units 12101 to 12104, and recognizes the pedestrian, the sound or image output unit 12052 controls the display unit 12062 in such a way that a rectangular contour line for emphasis is displayed to be superimposed onto the recognized pedestrian. Furthermore, the sound or image output unit 12052 may control the display unit 12062 to display an icon or the like that indicates the pedestrian, in a desired position.

An example of a vehicle control system to which the technology according to the present disclosure can be applied has been described above. The technology according to the present disclosure can be applied to, for example, the imaging unit 12031 or the like in the configuration described above. By applying the technology according to the present disclosure to the imaging unit 12031, a captured image having a higher sensitivity can be obtained, and therefore object detection processing or distance detection processing using the image can be reliably performed.

<Configuration Examples of Stacked Type Solid-State Imaging Apparatus to which the Technology According to the Present Disclosure can be Applied>

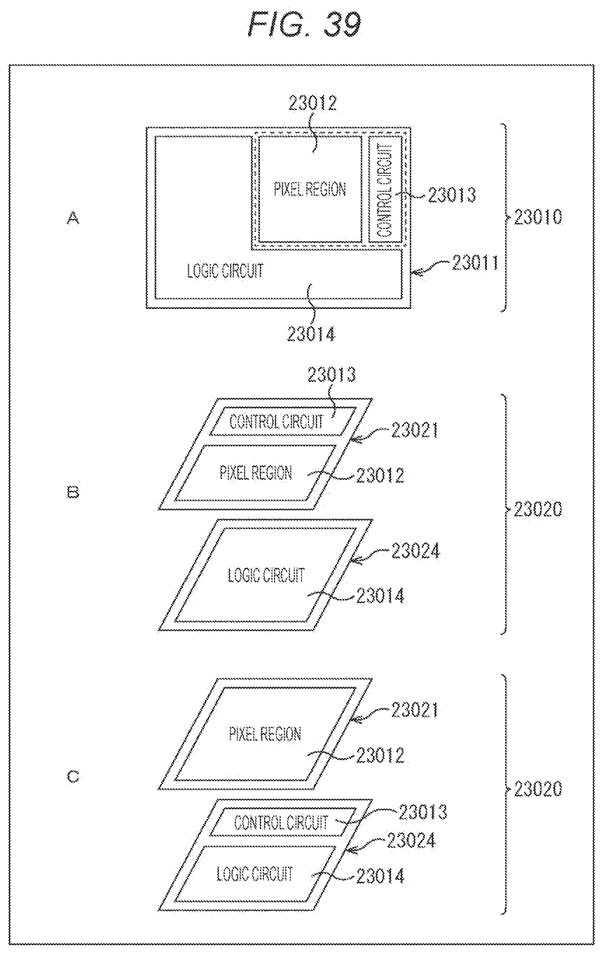

FIG. 39 is a diagram illustrating an outline of configuration examples of a stacked type solid-state imaging apparatus to which the technology according to the present disclosure can be applied.

A of FIG. 39 illustrates a schematic configuration example of a non-stacked type solid-state imaging apparatus. A solid-state imaging apparatus 23010 includes one die (a semiconductor substrate) 23011, as illustrated in A of FIG. 39. A pixel region 23012 in which pixels are arranged in an array shape, a control circuit 23013 that performs various types of control including the driving of a pixel, and the like, and a logic circuit 23014 that performs signal processing are mounted on this die 23011.

B and C of FIG. 39 illustrate schematic configuration examples of a stacked type solid-state imaging apparatus. A solid-state imaging apparatus 23020 is configured as one semiconductor chip in which two dies, a sensor die 23021 and a logic die 23024, have been stacked, and are electrically connected to each other, as illustrated in B and C of FIG. 39.

In B of FIG. 39, a pixel region 23012 and a control circuit 23013 are mounted on the sensor die 23021, and a logic circuit 23014 that includes a signal processing circuit that performs signal processing is mounted on the logic die 23024.

In C of FIG. 39, a pixel region 23012 is mounted on the sensor die 23021, and a control circuit 23013 and a logic circuit 23014 are mounted on the logic die 23024.

The technology according to the present disclosure can be applied to a solid-state imaging apparatus, as described above.

<Example of Combination of Configurations>

Note that the present technology can also employ the configurations described below.

(1) A sensor element including: a semiconductor layer in which an optical-to-electrical conversion element is formed, the optical-to-electrical conversion element receiving light in a predetermined wavelength range and performing optical-to-electrical conversion; a reflection suppressing part that suppresses reflection of the light, on a first surface serving as a side on which the light enters the semiconductor layer; and a transmission suppressing part that suppresses transmission through the semiconductor layer of the light that has been made incident from the first surface, on a second surface serving as a side that is opposite to the first surface of the semiconductor layer.

(2) The sensor element according to (1) described above, in which the transmission suppressing part is included in the semiconductor layer for at least some of a plurality of pixels that is arranged in an array shape, and when the second surface of the semiconductor layer is viewed in a plan view, the transmission suppressing part is provided at least in a region in which the optical-to-electrical conversion element included in each of the pixels is disposed, the region being obtained by removing a range in which a transistor used to drive each of the pixels is disposed.

(3) The sensor element according to (1) or (2) described above, in which the transmission suppressing part includes an uneven structure formed by digging a plurality of trenches at predetermined intervals, each of the trenches having a recessed shape with respect to the second surface of the semiconductor layer.

(4) The sensor element according to (1) or (2) described above, in which the transmission suppressing part includes an uneven structure formed by disposing a plurality of protruding structures at predetermined intervals, each of the protruding structures having a protruding shape with respect to the second surface of the semiconductor layer.

(5) The sensor element according to (4) described above, in which each of the plurality of protruding structures includes a dummy gate electrode that is formed in forming a gate electrode of a transistor that is used to drive a pixel including the optical-to-electrical conversion element, the dummy gate electrode being in a floating potential state or being fixed at a ground potential.

(6) The sensor element according to (1) or (2) described above, in which the transmission suppressing part includes an uneven structure formed by digging a plurality of trenches at predetermined intervals and disposing a plurality of protruding structures at predetermined intervals, each of the trenches having a recessed shape with respect to the second surface of the semiconductor layer, each of the protruding structures having a protruding shape with respect to the second surface of the semiconductor layer.

(7) The sensor element according to (1) or (2) described above, in which the transmission suppressing part includes an uneven structure formed by providing a plurality of quadrangular pyramid shapes or reversed quadrangular pyramid shapes on the second surface of the semiconductor layer at predetermined intervals, each of the quadrangular pyramid shapes or reversed quadrangular pyramid shapes including a slope having an inclination angle according to a plane index of a crystal surface of a single crystal silicon wafer that configures the semiconductor layer.

(8) The sensor element according to any of (1) to (7) described above, in which the reflection suppressing part includes an uneven structure formed by providing a plurality of quadrangular pyramid shapes or reversed quadrangular pyramid shapes on the first surface of the semiconductor layer at predetermined intervals, each of the quadrangular pyramid shapes or reversed quadrangular pyramid shapes including a slope having an inclination angle according to a plane index of a crystal surface of a single crystal silicon wafer that configures the semiconductor layer.

(9) The sensor element according to (1) or (2) described above, in which the reflection suppressing part includes a first uneven structure formed by providing a plurality of quadrangular pyramid shapes or reversed quadrangular pyramid shapes on the first surface of the semiconductor layer at predetermined intervals, each of the quadrangular pyramid shapes or reversed quadrangular pyramid shapes including a slope having an inclination angle according to a first plane index of a crystal surface of a single crystal silicon wafer that configures the semiconductor layer, and the transmission suppressing part includes a second uneven structure formed by providing a plurality of quadrangular pyramid shapes or reversed quadrangular pyramid shapes on the second surface of the semiconductor layer at predetermined intervals, each of the quadrangular pyramid shapes or reversed quadrangular pyramid shapes including a slope having an inclination angle according to a second plane index that is different from the first plane index.

(10) The sensor element according to (9) described above, in which the reflection suppressing part and the transmission suppressing part are formed in such a way that an orientation of the first uneven structure is relatively offset by 45 degrees with respect to an orientation of the second uneven structure.

(11) The sensor element according to (9) described above, in which a plane index of the crystal surface that is used to form the first uneven structure is 110, and a plane index of the crystal surface that is used to form the second uneven structure is 111.

(12) The sensor element according to (9) described above, in which a plane index of the crystal surface that is used to form the first uneven structure is 111, and a plane index of the crystal surface that is used to form the second uneven structure is 110.

(13) The sensor element according to any of (1) to (12) described above, further including: an element isolation structure that isolates a plurality of the pixels from each other, and is formed by digging in the semiconductor layer.

(14) The sensor element according to (13) described above, in which the element isolation structure is formed to penetrate the semiconductor layer.

(15) The sensor element according to any of (1) to (14) described above, in which high-concentration P-type impurities are implanted into a region around the transmission suppressing part on the second surface of the semiconductor layer, the region around the transmission suppressing part including a region in which the transmission suppressing part is provided, or the region around the transmission suppressing part is electrically pinned by a film having a negative fixed charge.

(16) The sensor element according to any of (1) to (15) described above, in which a filter layer is disposed on a side of the first surface, the light received by the optical-to-electrical conversion element being selectively transmitted through the filter layer.

(17) The sensor element according to any of (1) to (16) described above, in which the first surface of the semiconductor layer includes a flat surface, and the reflection suppressing part includes an antireflection film that selectively prevents reflection of light in a near infrared wavelength band.

(18) The sensor element according to (17) described above, in which the reflection suppressing part includes an antireflection film that has been formed to have a thickness according to a center wavelength of light in a desired wavelength band, the antireflection film selectively reflecting the light, and the antireflection film includes a medium having a refractive index that is greater than a refractive index of silicon dioxide and is smaller than a refractive index of silicon.

(19) The sensor element according to any of (1) to (18) described above, in which a gate electrode of a transfer transistor is embedded up to a predetermined depth from the second surface of the semiconductor layer, the transfer transistor transferring an electric charge that has occurred in the optical-to-electrical conversion performed by the optical-to-electrical conversion element.

(20) An electronic device including: a sensor element that includes: a semiconductor layer in which an optical-to-electrical conversion element is formed, the optical-to-electrical conversion element receiving light in a predetermined wavelength range and performing optical-to-electrical conversion; a reflection suppressing part that suppresses reflection of the light, on a first surface serving as a side on which the light enters the semiconductor layer; and a transmission suppressing part that suppresses transmission through the semiconductor layer of the light that has been made incident from the first surface, on a second surface serving as a side that is opposite to the first surface of the semiconductor layer.

Note that the present embodiments are not limited to the embodiments described above, and various changes can be made without departing from the gist of the present disclosure. Furthermore, the effects described herein are only illustrative and are not restrictive, and other effects may be exhibited.

### REFERENCE SIGNS LIST

11 Pixel
21 Sensor substrate
22 On-chip lens layer
23 Wiring layer
24 Filter layer
31 Semiconductor layer
32 DTI
33 Reflection suppressing part
34 Transmission suppressing part
35 Flat surface
36 Optical-to-electrical converter
37 Effective pixel region
41 Microlens
51 Insulating film
52 Gate electrode
53 Interlayer insulating film
54 Multilayer interconnection
61 Color filter
71 Transfer transistor
72 Amplification transistor
73 Selection transistor
74 Reset transistor
75 FD unit
76 Vertical signal line

What is claimed is:

1. A sensor element comprising:
a semiconductor layer in which an optical-to-electrical conversion element is formed, the optical-to-electrical conversion element receiving light in a predetermined wavelength range and performing optical-to-electrical conversion;
a reflection suppressing part that suppresses reflection of the light, on a first surface serving as a side on which the light enters the semiconductor layer; and
a transmission suppressing part that suppresses transmission through the semiconductor layer of the light that has been made incident from the first surface, on a second surface serving as a side that is opposite to the first surface of the semiconductor layer.

2. The sensor element according to claim 1,
wherein the transmission suppressing part is included in the semiconductor layer for at least some of a plurality of pixels that is arranged in an array shape, and
when the second surface of the semiconductor layer is viewed in a plan view, the transmission suppressing part is provided at least in a region in which the optical-to-electrical conversion element included in each of the pixels is disposed, the region being obtained by removing a range in which a transistor used to drive each of the pixels is disposed.

3. The sensor element according to claim 1,
wherein the transmission suppressing part includes an uneven structure formed by digging a plurality of trenches at predetermined intervals, each of the trenches having a recessed shape with respect to the second surface of the semiconductor layer.

4. The sensor element according to claim 1,
wherein the transmission suppressing part includes an uneven structure formed by disposing a plurality of protruding structures at predetermined intervals, each of the protruding structures having a protruding shape with respect to the second surface of the semiconductor layer.

5. The sensor element according to claim 4,
wherein each of the plurality of protruding structures includes a dummy gate electrode that is formed in forming a gate electrode of a transistor that is used to drive a pixel including the optical-to-electrical conversion element, the dummy gate electrode being in a floating potential state or being fixed at a ground potential.

6. The sensor element according to claim 1,
wherein the transmission suppressing part includes an uneven structure formed by digging a plurality of trenches at predetermined intervals and disposing a plurality of protruding structures at predetermined intervals, each of the trenches having a recessed shape with respect to the second surface of the semiconductor layer, each of the protruding structures having a protruding shape with respect to the second surface of the semiconductor layer.

7. The sensor element according to claim 1,
wherein the transmission suppressing part includes an uneven structure formed by providing a plurality of quadrangular pyramid shapes or reversed quadrangular pyramid shapes on the second surface of the semiconductor layer at predetermined intervals, each of the quadrangular pyramid shapes or reversed quadrangular pyramid shapes including a slope having an inclination angle according to a plane index of a crystal surface of a single crystal silicon wafer that configures the semiconductor layer.

8. The sensor element according to claim 1,
wherein the reflection suppressing part includes an uneven structure formed by providing a plurality of quadrangular pyramid shapes or reversed quadrangular pyramid shapes on the first surface of the semiconductor layer at predetermined intervals, each of the quadrangular pyramid shapes or reversed quadrangular pyramid shapes including a slope having an inclination angle according to a plane index of a crystal surface of a single crystal silicon wafer that configures the semiconductor layer.

9. The sensor element according to claim 1,
wherein the reflection suppressing part includes a first uneven structure formed by providing a plurality of quadrangular pyramid shapes or reversed quadrangular pyramid shapes on the first surface of the semiconductor layer at predetermined intervals, each of the quadrangular pyramid shapes or reversed quadrangular pyramid shapes including a slope having an inclination angle according to a first plane index of a crystal surface of a single crystal silicon wafer that configures the semiconductor layer, and
the transmission suppressing part includes a second uneven structure formed by providing a plurality of quadrangular pyramid shapes or reversed quadrangular pyramid shapes on the second surface of the semiconductor layer at predetermined intervals, each of the quadrangular pyramid shapes or reversed quadrangular pyramid shapes including a slope having an inclination angle according to a second plane index that is different from the first plane index.

10. The sensor element according to claim 9,
wherein the reflection suppressing part and the transmission suppressing part are formed in such a way that an orientation of the first uneven structure is relatively offset by 45 degrees with respect to an orientation of the second uneven structure.

11. The sensor element according to claim 9,
wherein a plane index of the crystal surface that is used to form the first uneven structure is 110, and
a plane index of the crystal surface that is used to form the second uneven structure is 111.

12. The sensor element according to claim 9,
wherein a plane index of the crystal surface that is used to form the first uneven structure is 111, and
a plane index of the crystal surface that is used to form the second uneven structure is 110.

13. The sensor element according to claim 2, further comprising:
an element isolation structure that isolates the plurality of pixels from each other, and is formed by digging in the semiconductor layer.

14. The sensor element according to claim 13,
wherein the element isolation structure is formed to penetrate the semiconductor layer.

15. The sensor element according to claim 1,
wherein high-concentration P-type impurities are implanted into a region around the transmission suppressing part on the second surface of the semiconductor layer, the region around the transmission suppressing part including a region in which the transmission suppressing part is provided, or the region around the transmission suppressing part is electrically pinned by a film having a negative fixed charge.

16. The sensor element according to claim 1,
wherein a filter layer is disposed on a side of the first surface, the light received by the optical-to-electrical conversion element being selectively transmitted through the filter layer.

17. The sensor element according to claim 1,
wherein the first surface of the semiconductor layer includes a flat surface, and
the reflection suppressing part includes an antireflection film that selectively prevents reflection of light in a near infrared wavelength band.

18. The sensor element according to claim 1,
wherein the reflection suppressing part includes an antireflection film that has been formed to have a thickness according to a center wavelength of light in a desired wavelength band, the antireflection film selectively reflecting the light, and
the antireflection film includes a medium having a refractive index that is greater than a refractive index of silicon dioxide and is smaller than a refractive index of silicon.

19. The sensor element according to claim 1,
wherein a gate electrode of a transfer transistor is embedded up to a predetermined depth from the second surface of the semiconductor layer, the transfer transistor transferring an electric charge that has occurred in the optical-to-electrical conversion performed by the optical-to-electrical conversion element.

20. An electronic device comprising:
a sensor element that includes:
a semiconductor layer in which an optical-to-electrical conversion element is formed, the optical-to-electrical conversion element receiving light in a predetermined wavelength range and performing optical-to-electrical conversion;
a reflection suppressing part that suppresses reflection of the light, on a first surface serving as a side on which the light enters the semiconductor layer; and
a transmission suppressing part that suppresses transmission through the semiconductor layer of the light that has been made incident from the first surface, on a second surface serving as a side that is opposite to the first surface of the semiconductor layer.
